(19) United States
(12) Patent Application Publication
(10) Pub. No.: US 2026/0016862 A1
(43) Pub. Date: Jan. 15, 2026

(54) HINGE AND FOLDABLE DISPLAY DEVICE

(71) Applicant: BOE Technology Group Co., Ltd., Beijing (CN)

(72) Inventors: Pengfei ZHOU, Beijing (CN); Lu LIU, Beijing (CN); Song ZHANG, Beijing (CN); Shiming SHI, Beijing (CN); Yonghui LIU, Beijing (CN); Yansheng PAN, Beijing (CN); Zihan GAO, Beijing (CN); Yanli WANG, Beijing (CN); Xuan TAO, Beijing (CN)

(73) Assignee: BOE Technology Group Co., Ltd., Beijing (CN)

(21) Appl. No.: 18/993,617

(22) PCT Filed: Apr. 16, 2024
(86) PCT No.: PCT/CN2024/088090

§ 371 Date: Jan. 13, 2025

(30) Foreign Application Priority Data
May 22, 2023 (CN) 202310579585.6

(51) Int. Cl. G06F 1/16

(52) U.S. Cl. CPC G06F 1/1681; G06F 1/1652

(57) ABSTRACT

A hinge includes at least two groups of first flip mechanisms, at least two groups of second flip mechanisms, and a transition mechanism. One group of the at least two groups of first flip mechanisms includes a first support base extending in a first direction and two first flip assemblies which are rotatably connected to the first support base and are oppositely arranged. One group of the at least two groups of second flip mechanisms includes a second support base extending in a second direction and two second flip assemblies which are rotatably connected to the second support base set and are oppositely arranged. Two groups of the at least two groups of first flip mechanisms are arranged on both sides of the transition mechanism in the first direction and are both rotatably connected to the transition mechanism.

### CROSS-REFERENCE TO RELATED APPLICATIONS

The present disclosure is a US national stage of international application No. PCT/CN2024/088090, filed on Apr. 16, 2024, which claims priority to Chinese Patent Application No. 202310579585.6, filed on May 22, 2023 and entitled “HINGE AND FOLDABLE DISPLAY DEVICE”, the entire content of each are incorporated herein by reference.

### TECHNICAL FIELD

The present disclosure relates to the technical field of electronic device, in particular to a hinge and a foldable display device.

### BACKGROUND

With the development of display technology, more and more display devices are equipped with foldable display screens. A display device equipped with the foldable display screen can realize the switching of the physical size of the display device, thereby greatly improving the use experience of a user.

However, the current display device equipped with the foldable display screen can only be folded or unfolded in one direction, resulting in poor flexibility in the use of the display device.

### SUMMARY

Embodiments of the present disclosure provide a hinge and a foldable display device, which can solve the problem that the foldable display device in the prior art can only be folded or unfolded in one direction, thereby resulting in poor flexibility in use. The technical solutions are as follows.

In one aspect, a hinge is provided. The hinge includes:
at least two groups of first flip mechanisms, wherein one group of the at least two groups of first flip mechanisms includes a first support base extending in a first direction and two first flip assemblies which are rotatably connected to the first support base and are oppositely arranged;
at least two groups of second flip mechanisms, wherein one group of the at least two groups of second flip mechanisms includes a second support base extending in a second direction and two second flip assemblies which are rotatably connected to the second support base set and are oppositely arranged; and
a transition mechanism, wherein two groups of the at least two groups of first flip mechanisms are arranged on both sides of the transition mechanism in the first direction and are both rotatably connected to the transition mechanism; and two groups of the at least two groups of second flip mechanisms are arranged on both sides of the transition mechanism in the second direction and are both arranged separately from the transition mechanism;
where the first direction is intersected with the second direction.

Optionally, a first slide member is arranged at an end of the first support base close to the transition mechanism, the transition mechanism includes a first arc-shaped slide groove in cooperation with the first slide member, and at least a portion of the first slide member is within the first arc-shaped slide groove.

Optionally, the transition mechanism includes a first transition member and a second transition member fixedly connected to a side of the first transition member, and the first arc-shaped slide groove is between the first transition member and the second transition.

Optionally, the first slide member includes a first slide member body disposed in the first arc-shaped slide groove, and two limiting members fixedly connected to both sides of the first slide member body, and a portion of the second transition member is disposed between the two limiting members.

Optionally, the first support base includes a first support base body and a first support plate connected to a side of the first support base body, and one end of the first support plate close to the transition mechanism includes the first slide member; and
where a side of the first support plate away from the first support base body is flush with a side of the first transition member away from the second transition member, when the at least two groups of second flip mechanisms are in an unfolded state.

Optionally, the second support base includes a second support base body, a second support plate connected to one side of the second support base body, and an avoidance ramp fixedly connected to one end of the second support plate close to the transition mechanism; the avoidance ramp is arranged separately from the transition mechanism; and an angle between a surface of the avoidance ramp away from the second support base body and a surface of the second support plate away from the second support base body is an obtuse angle.

Optionally, the transition mechanism further includes a third support seat body, and the second transition member is connected to a side of the third support seat body; and
where both a side of the third support seat body close to the first support base body and a side of the third support seat body close to the second support base body are arc-shaped.

Optionally, the first flip assembly includes a first swing arm, a first adapter fixing member and a first flip plate;
one end of the first swing arm is rotatably connected to the first support base; the first adapter fixing member includes a first straight slide groove, and the other end of the first swing arm is slidably connected to the first adapter fixing member within the first straight slide groove; and the first flip plate is rotatably connected to the first adapter fixing member; and
where a side of the first flip plate is configured to be abutted against a back of a flexible display panel in a foldable display device, and the first adapter fixing member is configured to be fixedly connected to a housing of the foldable display device, and the housing is fixedly connected to the back of the flexible display panel.

Optionally, the first adapter fixing member includes a first slide portion and a second slide portion on at least one side of the first slide portion;
the first slide portion includes the first straight slide groove, and a second arc-shaped slide groove is defined in a side of the second slide portion away from the first slide portion; and
the first flip plate includes a first flip plate body, and a second slide member fixedly connected to a side of the first flip plate body away from the flexible display panel, and at least a portion of the second slide member is within the second arc-shaped slide groove.

Optionally, the first slide portion further includes a first hollow groove in communication with the first straight slide groove, and a portion of the first swing arm within the first straight slide groove includes a second hollow groove in communication with the first hollow groove, and an inner wall of the second hollow groove includes a third slide member; and
the first flip plate further includes a raised portion fixedly connected to a side of the first flip plate body away from the flexible display panel, the raised portion successively passes through the first hollow groove and the second hollow groove, and a portion of the raised portion within the second hollow groove includes a third arc-shaped slide groove; and
where at least a portion of the third slide member is within the third arc-shaped groove.

Optionally, a side of the first straight slide groove includes a limiting slide groove, an extension direction of the limiting slide groove is parallel to an extension direction of the first straight slide groove; and
a portion of the first swing arm disposed within the first straight slide groove includes a limiting slide member, and at least a portion of the limiting slide member is disposed within the limiting slide groove.

Optionally, one group of the first flip mechanisms further includes two first synchronizing shafts, both of the two first synchronizing shafts are fixed in the first support base, and each of the two first synchronizing shafts is rotatably connected to one end of each of two the first swing arms in two first flip assemblies.

Optionally, one group of the first flip mechanisms further includes two second synchronizing shafts disposed between the two first synchronizing shafts, two first synchronous gears respectively sleeved on the two second synchronizing shafts, and the two first synchronous gears on the two second synchronizing shafts are engaged with each other; and one end of the first swing arm includes a plurality of first outer teeth engaging with the first synchronous gear.

Optionally, one group of the first flip mechanisms further includes first torsion assemblies respectively connected to the two first synchronizing shafts, and the first torsion assemblies are configured to provide a damping force in response to rotation of two of the first flip assemblies relative to the first support base.

Optionally, the first flip assembly further includes a second swing arm and a second adapter fixing member; and
one end of the second swing arm is rotatably connected to the first support base and the other end of the second swing arm is rotatably connected to the second adapter fixing member; and the second adapter fixing member is rotatably connected to the first flip plate; and
where the second adapter fixing member is configured to be fixedly connected to the housing.

Optionally, at least one side of the second adapter fixing member includes a fourth arc-shaped slide groove; and
the first flip plate further includes a fourth slide member fixedly connected to a side of the first flip plate body away from the flexible display panel, and at least a portion of the fourth slide member is within the fourth arc-shaped slide groove.

Optionally, the first support base includes a fifth arc-shaped slide groove, one end of the second swing arm includes a fifth slide member cooperating with the fifth arc-shaped slide groove, and at least a portion of the fifth slide member is within the fifth arc-shaped slide groove.

Optionally, the first flip assembly further includes a first connecting shaft fixed to a side of the second adapter fixing member away from the flexible display panel, and an end of the second swing arm away from the first support base is rotatably connected to the first connecting shaft.

Optionally, the second adapter fixing member and the first adapter fixing member are of one-piece structure.

Optionally, the second flip assembly includes a first drive rod and a second flip plate; and
one end of the first drive rod is rotatably connected to the second support base, and the other end of the first drive rod is fixedly connected to the second flip plate; and
where one side of the second flap is configured to abut against a back of a flexible display panel in a foldable display device; a first axis of an end of the first drive rod around which the end of the first drive rod is rotated relative to the second support base is on a side of the second support base close to the flexible display panel, and a specific distance is defined between the first axis and the second support base.

Optionally, the second support base includes a sixth arc-shaped slide groove, one end of the first actuating rod includes a sixth slide member that cooperates with the sixth arc-shaped slide groove, and at least a portion of the sixth slide member is disposed within the sixth arc-shaped slide groove.

Optionally, the second flip assembly further includes a second drive rod and a second connecting shaft; and
one end of the second drive rod is rotatably connected to the second support base and the other end of the second drive rod is fixedly connected to one end of the second connecting shaft, an end of the first drive rod away from the second support base includes a second straight slide groove, and the other end of the second connecting shaft is slidingly connected to the first drive rod within the second straight slide groove; and
where a second axis of an end of the second drive rod around which the end of the second drive rod is rotated relative to the second support base is within the second support base, and the second axis is parallel to the first axis and an axis of the second connecting shaft.

Optionally, one group of the second flip mechanisms further includes two third synchronizing shafts, both of the third synchronizing shafts are fixed within the second support base, and each of the two third synchronizing shafts is rotatably connected to one end of each of two second drive rods in the two second flip assemblies.

Optionally, one group of the second flip mechanism furthers includes two fourth synchronizing shafts disposed between the two third synchronizing shafts and two second synchronizing gears respectively sleeved on the two fourth synchronizing shafts, the two second synchronizing gears on the two fourth synchronizing shafts are engaged with each other, and a plurality of second external teeth engaging with one second synchronizing gear are arranged at one end of the second actuating rod.

Optionally, one group of the second flip mechanisms further includes two second torsion assemblies each of which is connected to each of the two third synchronizing shafts, and the two second torsion assemblies are configured to provide a damping force in response to rotation of the two second flip assemblies relative to the second support base.

Optionally, a length of the second straight slide groove is less than or equal to 3 mm.

Optionally, one first support base in each group of first flip mechanisms located on one side of the transition mechanism is of one-piece structure, one first support base in each group of first flip mechanisms on the other side of the transition mechanism is of one-piece structure, and a length of the first support base is greater in the first direction than a length of the first support base on the other side of the transition mechanism; and
one second support base in each of the groups of second flip mechanisms located on one side of the transition mechanism is of one-piece structure, one second support base in each of the groups of second flip mechanisms located on the other side of the transition mechanism is of one-piece structure and a length of the second support base on one side of the transition mechanism is equal to a length of the second support base on the other side of the transition mechanism in the second direction.

Optionally, a maximum rotation angle of the first flip assembly relative to the first support base is greater than or equal to 90°, and a maximum rotation angle of the second flip assembly relative to the second support base is less than or equal to 45°.

In another aspect, a foldable display device is provided, and the foldable display device including:
a flexible display panel, a housing and a hinge. The housing is fixedly connected to a back of the flexible display panel and is fixedly connected to the hinge, and the hinge is the hinge as given in any of the foregoing.

Technical solutions provided by embodiments of the present disclosure bring the following beneficial effects.

A hinge that may include at least two groups of first flip mechanisms, at least two groups of second flip mechanisms, and a transition mechanism. Since the at least two groups of first flip mechanisms, the at least two groups of second flip mechanisms and the transition mechanism are provided in the hinge, there are two groups of first flip mechanisms distributed on both sides of the transition mechanism and rotatably connected to the transition mechanism, and there are two groups of second flip mechanisms distributed on both sides of the transition mechanism and provided separately from the transition mechanism. Thus, the folding or unfolding of the foldable display device around a first direction can be achieved by the first flip mechanism, and the folding or unfolding of the foldable display device around a second direction can be realized by the second flip mechanism. In other words, the foldable display device can be folded or unfolded in two directions, which effectively improves the flexibility of the use of the foldable display device.

### BRIEF DESCRIPTION OF DRAWINGS

In order to more clearly illustrate the technical solutions in the embodiments of the present disclosure, the accompanying drawings to be used in the description of the embodiments will be briefly introduced below, and it will be obvious that the accompanying drawings in the following description are only some of the embodiments of the present disclosure, and other accompanying drawings can be obtained according to these drawings for the people of ordinary skill in the field without putting forth any creative work.

FIG. 1 is a top view of a hinge according to an embodiment of the present disclosure;

FIG. 2 is a bottom view of the hinge shown in FIG. 2;

FIG. 3 is a schematic view of a structure of the hinge shown in FIG. 2;

FIG. 4 is an effect schematic diagram of a hinge according to an embodiment of the present disclosure after a first flip mechanism is folded;

FIG. 5 is an effect schematic diagram of a hinge according to an embodiment of the present disclosure after a second flip mechanism is folded;

FIG. 6 is an exploded schematic diagram of part of a structure of a hinge according to an embodiment of the present disclosure;

FIG. 7 is an exploded schematic diagram of part of a structure of another hinge according to an embodiment of the present disclosure;

FIG. 8 is a schematic diagram of an assembly of the hinge shown in FIG. 6 or FIG. 7;

FIG. 9 is an exploded schematic diagram of a first support plate and a transition mechanism according to an embodiment of the present disclosure;

FIG. 10 is a schematic diagram of an assembly of the first support plate and the transition mechanism shown in FIG. 9;

FIG. 11 is an exploded schematic diagram of part of a structure of yet another hinge according to an embodiment of the present disclosure;

FIG. 12 is an exploded schematic diagram of part of a structure of yet another hinge according to an embodiment of the present disclosure;

FIG. 13 is a schematic diagram of part of the structure of the hinge shown in FIG. 12 after assembly;

FIG. 14 is an exploded schematic diagram of a first flip mechanism according to an embodiment of the present disclosure;

FIG. 15 is a schematic diagram of an assembly of the first flip mechanism shown in FIG. 14;

FIG. 16 is an exploded schematic diagram of part of a structure of a first flip mechanism according to an embodiment of the present disclosure;

FIG. 17 is an exploded schematic diagram of part of a structure of another first flip mechanism according to an embodiment of the present disclosure;

FIG. 18 is a schematic diagram of the assembly of the first flip mechanism shown in FIG. 17;

FIG. 19 is an exploded schematic diagram of yet another first flip mechanism according to an embodiment of the present disclosure;

FIG. 20 is a schematic diagram of an assembly of the first flip mechanism shown in FIG. 19;

FIG. 21 is a schematic diagram of a structure of a second base according to an embodiment of the present disclosure;

FIG. 22 is an exploded schematic diagram of part of a structure of a second flip mechanism according to an embodiment of the present disclosure;

FIG. 23 is a schematic diagram of an assembly of the second flip mechanism shown in FIG. 22;

FIG. 24 is a sectional view of a second drive rod connected to a first drive rod in a second flip assembly provided by embodiments of the present disclosure;

FIG. 25 is a schematic view of a structure of a foldable display device according to an embodiment of the present disclosure;

FIG. 26 is an exploded schematic view of the foldable display device shown in FIG. 25;

FIG. 27 is an exploded schematic view of another structure of the foldable display device shown in FIG. 25; and

FIG. 28 is a schematic diagram of a structure of another foldable display device provided by embodiments of the present disclosure.

Definite embodiments of the present disclosure have been shown by the above-described accompanying drawings, which will be described in greater detail later. These accompanying drawings and textual descriptions are not intended to limit the scope of the present disclosure idea in any way, but rather to illustrate the concepts of the present disclosure for those skilled in the art by reference to particular embodiments.

### DETAILED DESCRIPTION

In order to make the purpose, technical solutions and advantages of the present disclosure clearer, embodiments of the present disclosure will be further described in detail below with reference to the accompanying drawings.

A hinge provided by embodiments of the present disclosure can be applied in a foldable display device, and under different conditions of use requirements, the user can fold or unfold the foldable display device in different directions to meet different needs of the user. For example, when a user needs to carry the foldable display device with him/her, he/she can fold it in one direction to reduce its size so as to enhance portability; and when the user is using the foldable display device, he/she can unfold it to provide a larger display area and an operation area, so as to enhance the convenience of use. Alternatively, it can be used after being folded at a certain angle in the other direction from the unfolded state to meet different usage scenarios. In practice, the type of foldable display device can be divided into various types, for example, it can be a mobile phone, a tablet computer, a laptop computer, an e-book and so on. The structure of the hinge in the foldable display device will be described in detail in the following embodiments.

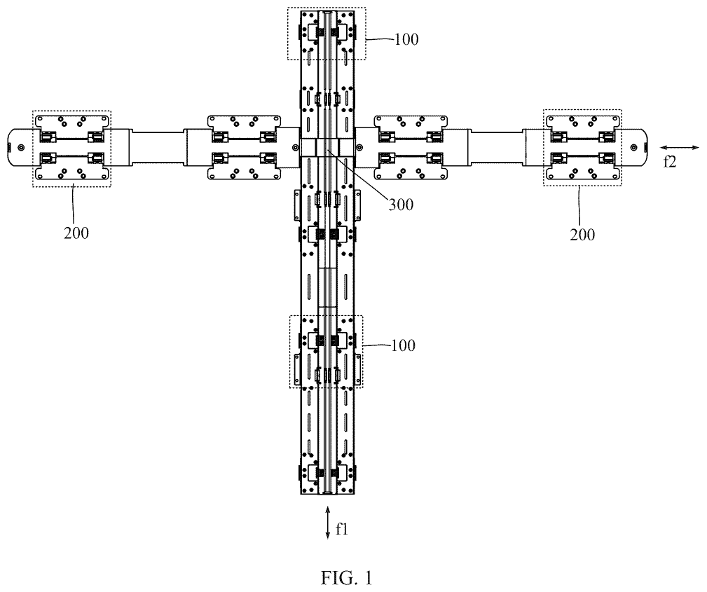

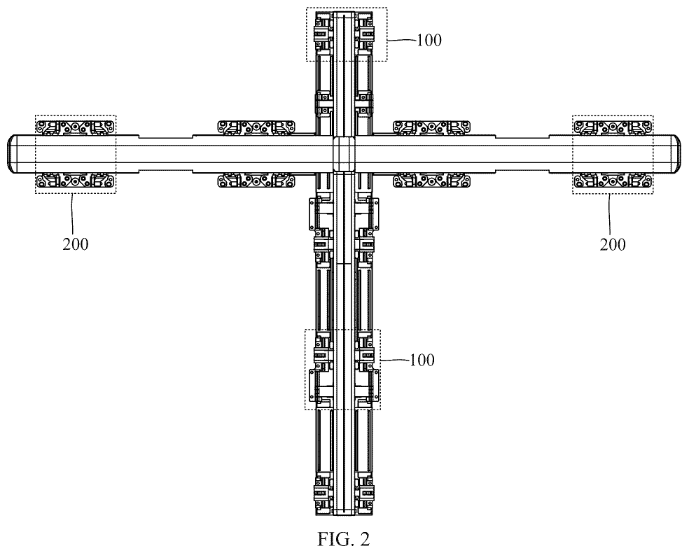

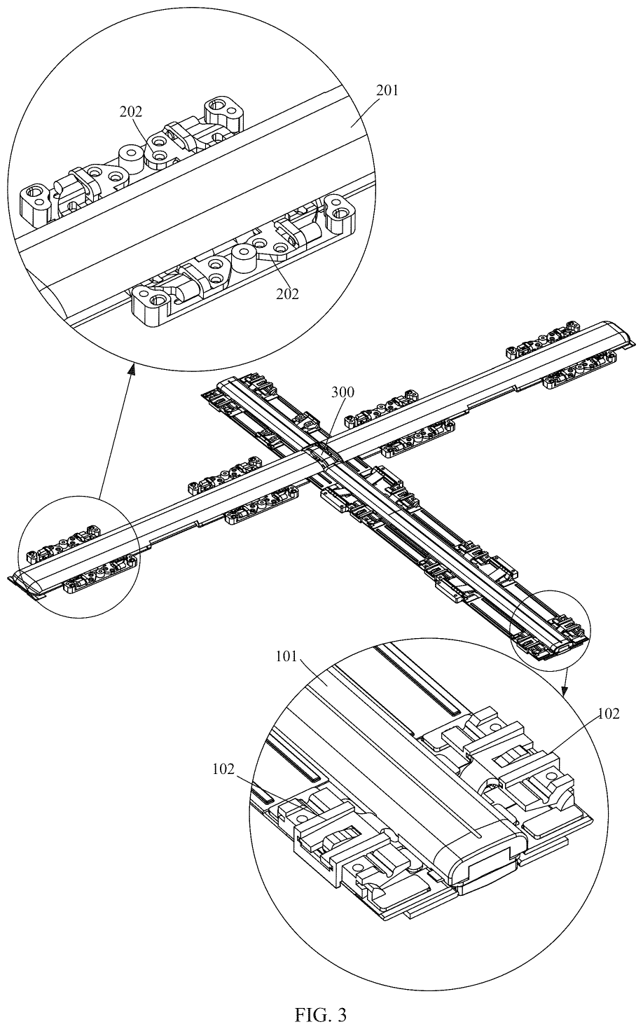

Referring to FIGS. 1, 2 and 3, FIG. 1 is a top view of a hinge according to an embodiment of the present disclosure, FIG. 2 is a bottom view of the hinge shown in FIG. 2, and FIG. 3 is a schematic view of a structure of the hinge shown in FIG. 2. The hinge may include at least two groups of first flip mechanisms 100, at least two groups of second flip mechanisms 200 and a transition mechanism 300.

The group of first flip mechanisms 100 in the hinge may include a first support base 101 extending along a first direction f1, and two first flip assemblies 102 oppositely arranged and rotatably connected to the first support base 101.

The group of second flip mechanisms 200 in the hinge may include: a second support base 201 extending along a second direction f2, and two second flip assemblies 202 oppositely arranged and rotatably connected to the second support base 201.

Among the at least two groups of first flip mechanisms 100 in the hinge, two groups of first flip mechanisms 100 are distributed on both sides of the transition mechanism 300 in a first direction f1, and both are rotatably connected to the transition mechanism 300. Among the at least two groups of second flip mechanisms 200 in the hinge, two groups of second flip mechanisms 200 are distributed on both sides of the transition mechanism 300 in the second direction f2, and both are provided separately from the transition mechanism 300. The first direction f1 intersects the second direction f2, for example, this first direction f1 may be perpendicular to the second direction f2. Exemplarily, the number of groups of first flip mechanisms 100 in the hinge may be at least two groups, and the at least two groups of first flip mechanism 100 may be arranged in sequence along the first direction f1. For example, there may be two groups, three groups, or four groups, etc., which may be adaptively arranged according to a boundary dimension of the foldable display device in the first direction f1. The number of groups of second flip mechanisms 200 in the hinge may be at least two groups, and the two groups of second flip mechanisms 200 may be arranged in sequence along the second direction. For example, there may be two, three or four groups, which may be adaptively arranged according to a boundary dimension of the foldable display device in the second direction f2.

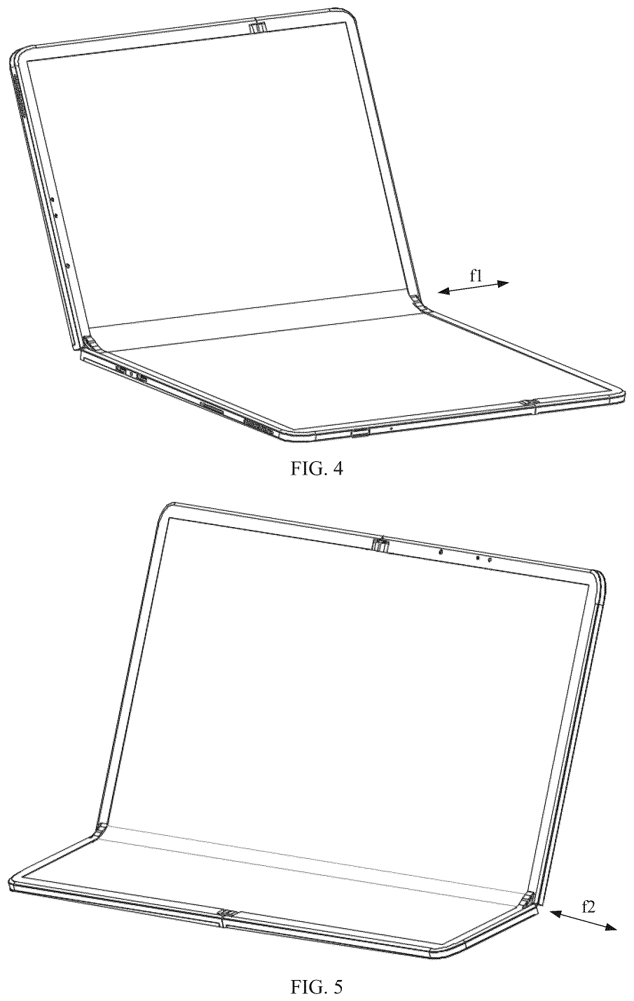

For example, referring to FIG. 4, an effect schematic diagram of a hinge according to an embodiment of the present disclosure after a first flip mechanism is folded is illustrated. When the hinge is switched between the unfolded state and the folded state, under the action of an external force, two oppositely arranged first flip assemblies 102 in the first flip mechanism 100 distributed on both sides of the transition mechanism 300 can rotate relative to each other around different directions and drive the second flip mechanism 200 to rotate. At this time, a flexible display panel in the foldable display device integrated with a hinge can be folded or unfolded around the first direction f1 under the driving action of the first flip mechanism 100. Alternatively, please refer to FIG. 5, which is an effect schematic diagram of a hinge according to an embodiment of the present disclosure after a second flip mechanism is folded. When the hinge is switched between the unfolded state and the folded state, under the action of an external force, two oppositely arranged second flip assemblies 202 in the second flip mechanism 200 distributed on both sides of the transition mechanism 300 can rotate relative to each other around different directions, and the first flip mechanism 100 is driven to rotate by the transition mechanism 300. At this time, the flexible display panel in the foldable display device integrated with a hinge can be folded or unfolded around the second direction f2 under the driving action of the second flip mechanism 200.

In an embodiment of the present disclosure, since at least two groups of first flip mechanisms 100, at least two groups of second flip mechanisms 200, and the transition mechanism 300 are provided in the hinge, there are two groups of first flip mechanisms 100 distributed on both sides of the transition mechanism 300 and rotatably connected to the transition mechanism 300, and there are two groups of second flip mechanisms 200 distributed on both sides of the transition mechanism 300 and provided separately from the transition mechanism 300. Thus, the folding or unfolding of the foldable display device around the first direction f1 can be achieved by the first flip mechanism 100, and the folding or unfolding of the foldable display device around the second direction f2 can be achieved by the second flip mechanism 200. In other words, the foldable display device can be folded or unfolded in two directions, which effectively improves the flexibility of the use of the foldable display device.

In summary, embodiments of the present disclosure provide a hinge that may include: at least two groups of first flip mechanisms, at least two groups of second flip mechanisms, and a transition mechanism. Since the at least two groups of first flip mechanisms, the at least two groups of second flip mechanisms and the transition mechanism are provided in the hinge, there are two groups of first flip mechanisms distributed on both sides of the transition mechanism and rotatably connected to the transition mechanism, and there are two groups of second flip mechanisms distributed on both sides of the transition mechanism and provided separately from the transition mechanism. Thus, the folding or unfolding of the foldable display device around a first direction can be achieved by the first flip mechanism, and the folding or unfolding of the foldable display device around a second direction can be realized by the second flip mechanism. In other words, the foldable display device can be folded or unfolded in two directions, which effectively improves the flexibility of the use of the foldable display device.

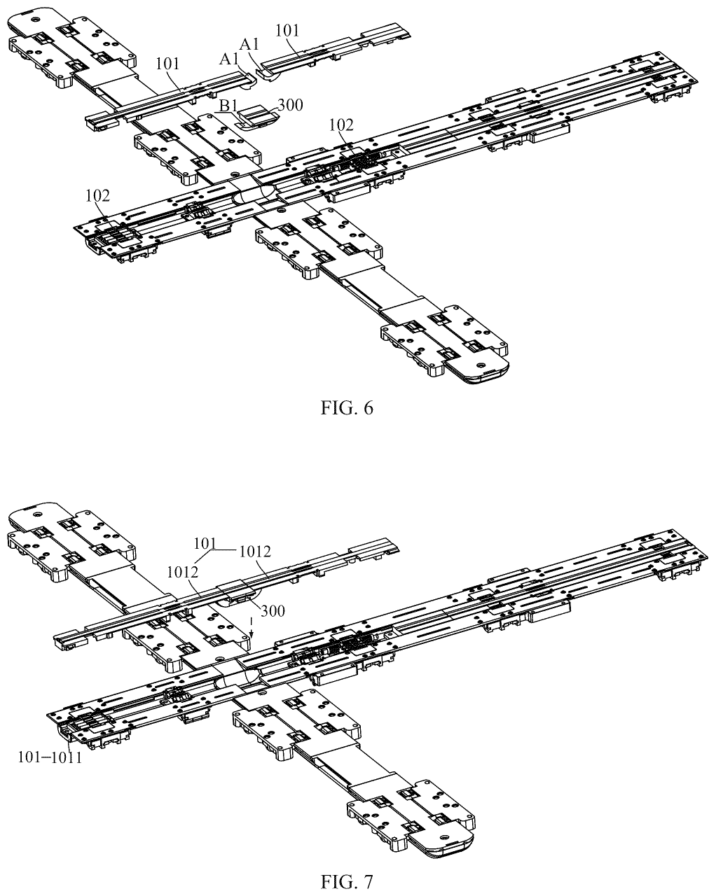

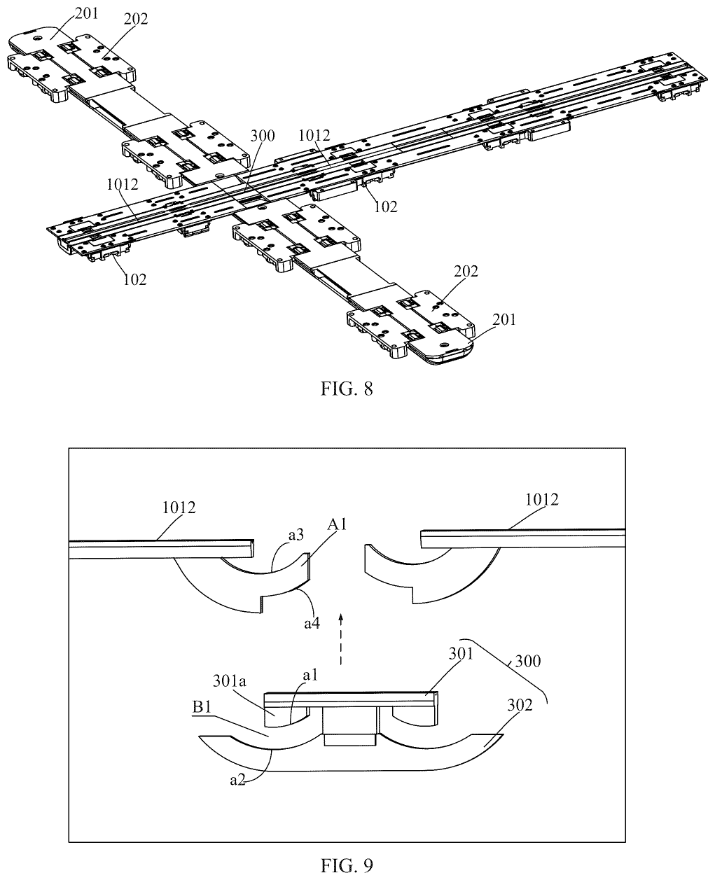

Optionally, referring to FIGS. 6, 7, and 8, FIG. 6 is an exploded schematic diagram of part of a structure of a hinge according to an embodiment of the present disclosure, FIG. 7 is an exploded schematic diagram of part of a structure of another hinge according to an embodiment of the present disclosure, and FIG. 8 is a schematic diagram of an assembly of the hinge shown in FIG. 6 or FIG. 7. One end of the first support base 101 in the first flip mechanism 100 in the hinge close to the transition mechanism 300 may have a first slide member A1, the transition mechanism 300 may have a first arc-shaped slide groove B1 that cooperates with the first slide member A1, and at least a portion of the first slide member A1 may be disposed within the first arc-shaped slide groove B1. In the present disclosure, the first support bases 101 in the two groups of first flip mechanisms 100 distributed respectively on both sides of the transition mechanism 300 in the first direction f1 may both have the first slide member A1. In this case, one end of the first support base 101 close to the transition mechanism 300 is provided with the first slide member A1, the first arc-shaped slide groove B1 cooperating with the first slide member A1 is provided in the transition mechanism 300, and the first slide member A1 slides in the first arc-shaped slide groove B1, so as to realize a stable rotational connection between the first support base 101 and the transition mechanism 300. Exemplarily, the number of the first arc-shaped slide groove B1 in the transition mechanism 300 is two, and the first slide members A1 of the two first support bases 101 located on both sides of the transition mechanism 300 close to the transition mechanism 300 can slide within corresponding first arc-shaped slide grooves B1.

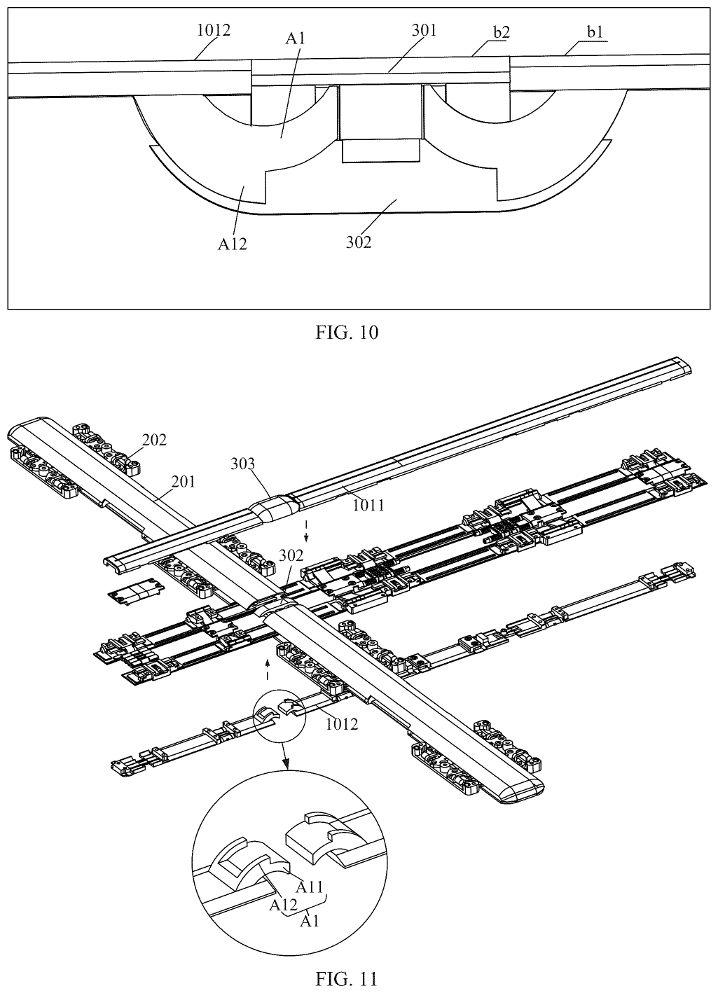

In this embodiment of the present disclosure, in order to see the structure of the transition mechanism more clearly, reference may be made to FIG. 9 and FIG. 10. FIG. 9 is an exploded schematic diagram of a first support plate and a transition mechanism according to an embodiment of the present disclosure, and FIG. 10 is a schematic diagram of an assembly of the first support plate and the transition mechanism shown in FIG. 9. The transition mechanism 300 in the hinge may include: a first transition member 301, and a second transition member 302 fixedly connected to one side of such first transition member 301. The first arc-shaped slide groove B1 in the transition mechanism 300 may be disposed between the first transition member 301 and the second transition member 302. In the present disclosure, one side of the first transition member 301 close to the second transition member 302 has a limiting block 301a, one surface of the limiting block 301a close to the second transition member 302 has a first cambered surface a1, and the side of the second transition member 302 close to the first transition member 301 has a second cambered surface a2, and the first arc-shaped slide groove B1 is formed between the first cambered surface a1 and the second cambered surface a2. The first slide member A1 has a third cambered surface a3 and a fourth cambered surface a4 which are oppositely arranged, the third cambered surface a3 abuts against the first cambered surface a1, and the fourth cambered surface a4 abuts against the second cambered surface a2.

Optionally, referring to FIGS. 9, 10, and 11, FIG. 11 is an exploded schematic diagram of part of a structure of yet another hinge according to an embodiment of the present disclosure. The first slide member A1 in the first support base 101 may include: a first slide member body A11 disposed in the first arc-shaped slide groove B1 in the transition mechanism 300, and two limiting members A12 fixedly connected to two sides of the first slide member body A11. A portion of a second transition member 302 in the transition mechanism 300 may be disposed between the two limiting members A12. In this case, the first slide member body A11 in the first slide member A1 is arranged in the first arc-shaped slide groove B1, the portion of the second transition member 302 is disposed between the two limiting members A12 in the first slide member A1, so that during the sliding process of the first slide member A1 relative to the first arc-shaped slide groove B1, the two limiting members A12 cooperate with the second transition member 302 to achieve a limiting effect on the first slide member A1 during the sliding process, so as to prevent the undesirable phenomenon of dislocation, and further ensure a relative position accuracy of the first slide members A1 in the first support base 101 on both sides of the transition mechanism 300 in the process of sliding relative to the first arc-shaped slide groove B1 in the transition mechanism 300.

In an embodiment of the present disclosure, as shown in FIGS. 7-11,, the first support base 101 in the first flip mechanism 100 may include: a first support base body 1011, and a first support plate 1012 connected to one side of the first support base body 1011. One end of the first support plate 1012 close to the transition mechanism 300 may have the first slide member A1. In this case, when the at least two groups of second flip mechanisms 200 are in the unfolded state (i.e., the second flipping assembly 202 of the second flip mechanisms are not folded), a side b1 of the first support plate 1012 away from the first support base body 1011 may be flush with a side b2 of the first transition member 301 away from the second transition member 302. In this case, when the second flip mechanism 200 is in the unfolded state, the side b1 of the first support plate 1012 away from the first support base body 1011 is flush with the side b2 of the first transition member 301 away from the second transition member 302, so that, in such a state, the first support plate 1012 and the first transition member 301 can support the flexible display panel in the foldable display device.

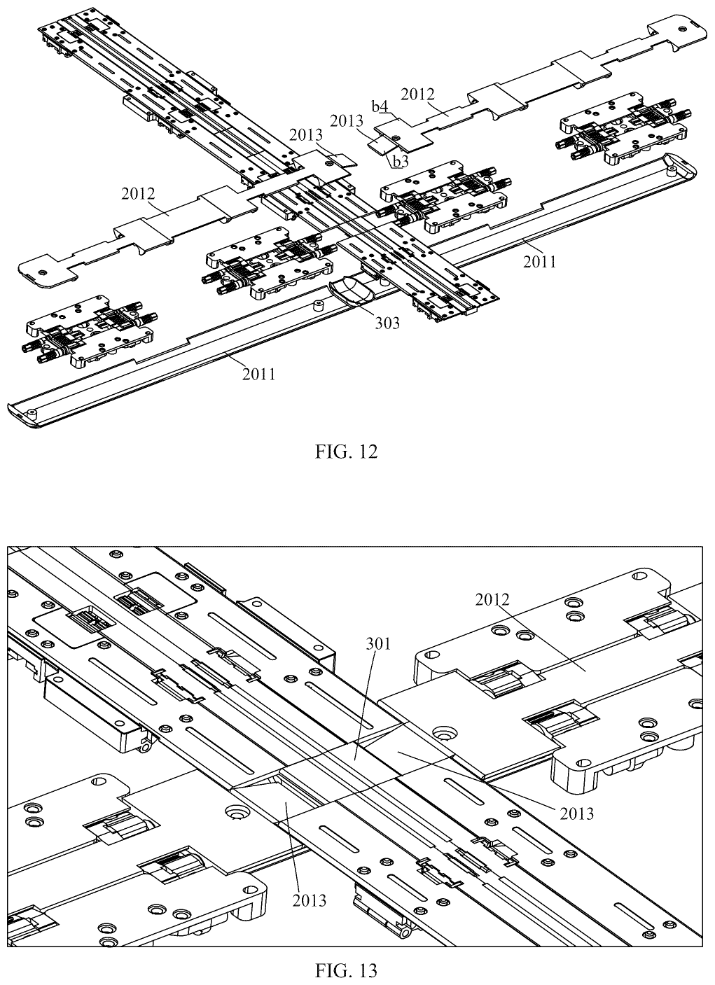

Optionally, please refer to FIG. 12 and FIG. 13. FIG. 12 is an exploded schematic diagram of part of a structure of yet another hinge according to an embodiment of the present disclosure, and FIG. 13 is a schematic diagram of part of the structure of the hinge shown in FIG. 12 after assembly. The second support base 201 in the second flip mechanism 200 may include: a second support base body 2011, a second support plate 2012 connected to one side of the second support base body 2011, and an avoidance ramp 2013 fixedly connected to one end of the second support plate 2012 close to the transition mechanism 300. The avoidance ramp 2013 is provided separately from the transition mechanism 300, and an angle between one surface b3 of the avoidance ramp 2013 away from the second support base body 2011 and one surface b4 of the second support plate 2012 away from the second support base body 2011 is an obtuse angle. In this case, the avoidance ramp 2013 which is provided separately from the transition mechanism 300 is arranged at one end of the second support plate 2012 in the second support base 201 close to the transition mechanism 300, and angle between one surface b3 of the avoidance ramp 2013 away from the second support base body 2011 and one surface b4 of the second support plate 2012 away from the second support base body 2011 is an obtuse angle, such that when the first flip assembly 102 in the first flip mechanism 100 is folded, the second flip mechanism 200 rotates synchronously, and the avoidance ramp plate 2013 ensures that the second support plate 2012 does not interfere with the transition mechanism 300.

In an embodiment of the present disclosure, as shown in FIGS. 11 and 12, the transition mechanism 300 in the hinge may further include: a third support seat body 303, and the second transition member 302 may be connected to one side of the third support seat body 303. In this case, the side of the third support seat body 303 close to the first support base body 1011 and the side of the third support seat body 303 close to the second support base body 2011 may both be arc-shaped. In this case, the third support seat body 303 is connected to the second transition member 302, such that the third support seat body 303 can protect the second transition member 302 in the transition mechanism 300. In addition, the side of the third support seat body 303 close to the first support base body 1011 is arc-shaped, so that when the second flip mechanism 200 is switched between the unfolding state and the folding state, the rotation between the third support seat body 303 and the first support base body 1011 can be smooth. The side of the third support seat body 303 close to the second support base body 2011 is arc-shaped, such that when the first flip mechanism 100 switches between the unfolded state and the folded state, the rotation between the third support seat body 303 and the second support base body 2011 can be smooth. In the present disclosure, an arc shape of the third support seat body 303 close to the side of the first support base body 1011 may be the same as a shape of a trajectory of the first support base body 1011 rotating relative to the third support seat body 303; and an arc shape of the third support seat body 303 close to the side of the second support base body 2011 may be the same as a shape of the trajectory of the second support base body 2011 rotating relative to the third support seat body 303.

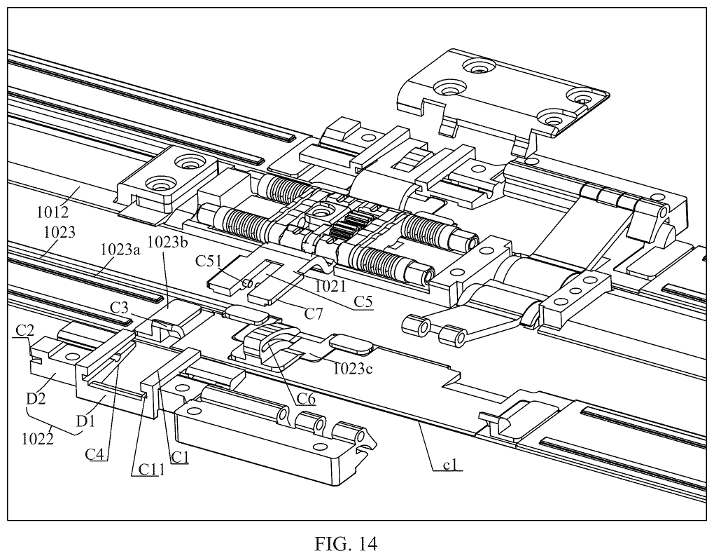

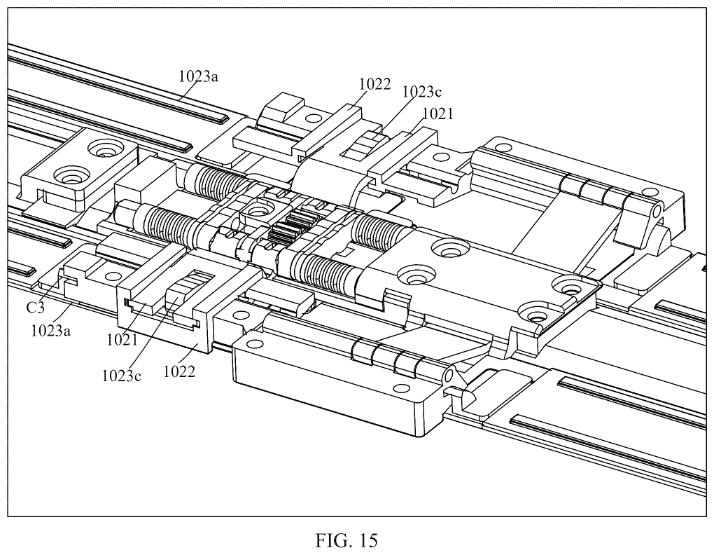

Optionally, refer to FIGS. 1, 2, 14, and 15. FIG. 14 is an exploded schematic diagram of a first flip mechanism according to an embodiment of the present disclosure, and FIG. 15 is a schematic diagram of an assembly of the first flip mechanism shown in FIG. 14. The first flip assembly 102 in the first flip mechanism 100 in the hinge may include: a first swing arm 1021, a first adapter fixing member, and a first flip plate 1023. One end of the first swing arm 1021 may be rotatably connected to the first support base 101, the first adapter fixing member 1022 may have a first straight slide groove C1, and the other end of the first swing arm 1021 is in the first adapter fixing member 1022 and is slidably connected to the first adapter fixing member 1022. The first flip plate 1023 may be rotatably connected to the first adapter fixing member 1022. One side c1 of the first flip plate 1023 may be used to abut against a back of the flexible display panel in the foldable display device, the first adapter fixing member 1022 may be used to fixedly connect to a housing in the foldable display device, and the housing may be fixedly connected to the back of the flexible display panel. Exemplarily, one first flip assembly 102 is used as an example to schematically illustrate the movement process of the first flip assembly: when the hinge is switched from the unfolded state to the folded state, under the action of an external force, the first adapter fixing member 1022 which is fixedly connected to the housing in the foldable display device may rotate around a counterclockwise direction. At this time, the first adapter fixing member 1022 drives the first swing arm 1021 and the first flip plate 1023 to rotate counterclockwise. During rotation, the flexible display panel usually has a tendency to stretch, and the first adapter fixing member 1022 connected to the housing in the foldable display device can have a degree of freedom to move away from the first support plate 1012, so that the housing can cooperate with the tendency of the movement of the flexible display panel to ensure that the housing does not have a phenomenon of pulling on the flexible display panel. In this case, the hinge can be in the shape of a “water drop”, also known as a water drop hinge.

When the hinge is switched from the folding state to the unfolding state, under the action of an external force, the first adapter fixing member 1022 fixedly connected to the housing in the foldable display device can be rotated in a clockwise direction, and at this time, the first adapter fixing member 1022 drives the first swing arm 1021 as well as the first flip plate 1023 to rotate around the clockwise direction. During rotation, the flexible display panel usually exhibits a tendency to contract, and the first adapter fixing member 1022 connected to the housing in the foldable display device can have a degree of freedom to move close to the first support plate 1012, so that the housing can cooperate with the tendency of the movement of the flexible display panel to ensure that the housing does not produce a pulling phenomenon on the flexible display panel. In addition, as the hinge is unfolded to the final state (i.e., the angle between the two first flip plates in the two first flip assemblies is 180 degrees), sides of the two first flip plates 1023 in the two first flip assemblies 102 close to the flexible display panel are co-planar, i.e., the sides of the two first flip plates 102 in the two first flip assemblies 102 close to the flexible display panel can form a flat support surface, and thus good support can be provided to the flexible screen. It should be noted that the two first flip assemblies 102 may be symmetrically provided relative to the first support base 101, and the basic structural composition and movement principle of the other first flip assembly 102 may be the same as that of the first flip assembly described in the above. Therefore, in the embodiment of the present disclosure, the structural composition and movement principle of the other first flip assembly 102 can be referred to the above description of the first flip assembly, and will not be repeated herein.

In an embodiment of the present disclosure, as shown in FIGS. 14 and 15, the first adapter fixing member 1022 in the first flip assembly 102 may include: a first slide portion D1, and a second sliding portion D2 disposed on at least one side of the first slide portion D1. The first slide portion D1 may have a first straight slide groove C1, and one side of the second sliding portion D2 away from the first slide portion D1 may have a second arc-shaped slide groove C2. The first flip plate 1023 in the first flip assembly 102 may include: a first flip plate body 1023a, and a second slide member 1023b fixedly connected to the side of the first flip plate body 1023a away from the flexible display panel, and at least a portion of the second slide member 1023b may be disposed in the second arc-shaped slide groove C2 in the second slide portion D2. In this case, while realizing the rotating connection between the first adapter fixing member 1022 and the first flip plate body 1023a by the second slide member 1023b and the second arc-shaped slide groove C2 in the second slide portion D2, the first flip plate body 1023a can rotate in accordance with a trajectory of the second arc-shaped slide groove C2. In the present disclosure, the first flip plate body 1023a and the second slide member 1023b may be a one-piece structure, and the second slide member 1023b may have a first arc-shaped slide block C3 matching the shape of the second arc-shaped slide groove C2, and the first arc-shaped slide block C3 can slide within the second arc-shaped slide groove C2.

Optionally, as shown in FIGS. 14 and 15, the first slide portion D1 in the first adapter fixing member 1022 may also have a first hollow groove C4 in communication with the first straight slide groove C1. The portion of the first swing arm 1021 in the first flip assembly 102 disposed within the first straight slide groove C1 may have a second hollow groove C5 in communication with the first hollow groove C4, and an inner wall of the second hollow groove C5 may have a third slide member C51. The first flip plate 1023 in the first flip assembly 102 may further include: a raised portion 1023c fixedly connected to a side of the first flip plate body 1023a that is away from the flexible display panel, the raised portion 1023c may pass through the first hollow groove C4 in the first slide portion D1 and the second hollow groove C5 in the first swing arm 1021 in sequence and a portion of the raised portion 1023c disposed within the second hollow groove C5 may have a third arc-shaped slide slot C6. At least a portion of the third slide member C51 may be disposed within the third arc-shaped slide slot C6. In this case, the raised portion 1023c is provided on the side of the first flip plate body 1023a away from the flexible display panel, the raised portion 1023c has the third arc-shaped slide groove C6, and an inner wall of the second hollow groove C5 in the first swing arm 1021 has a third slide member C51 (which may be a sliding post, for example) slidingly coupled with the third arc-shaped slide groove C6, so that the first flip plate body 1023a can rotate according to the trajectory of the third arc-shaped slide groove C6 while rotating according to the trajectory of the second arc-shaped slide groove C2. It is to be noted that, in the above embodiment, the second slide member 1023b and the second arc-shaped slide groove C2, and the third slide member C51 and the third arc-shaped slide groove C6 can be used separately, or, the second slide member 1023b and the second arc-shaped slide groove C2, and the third slide member C51 and the third arc-shaped slide groove C6 can be used together, and the embodiments of the present disclosure do not make any specific limitations in this regard.

In an embodiment of the present disclosure, as shown in FIGS. 14 and 15, a side of the first straight slide groove C1 in the first slide portion D1 in the first adapter fixing member 1022 may have a limiting slide groove C11, and an extension direction of the limiting slide groove C11 may be parallel to an extension direction of the first straight slide groove C1. The portion of the first swing arm 1021 that is disposed within the first straight slide groove C1 may have a limiting slide member C7, and at least a portion of the limiting slide member C7 may be disposed within the limiting slide groove C11. In this case, the limiting slide groove C11 is provided in the first slide portion D1, the portion of the first swing arm 1021 disposed within the first straight slide groove C1 of the first slide portion D1 may have the limiting slide member C7, so that when the first swing arm 1021 slides within the first straight slide groove C1, the first swing arm 1021 can be limited in a direction perpendicular to the first adapter fixing member 1022.

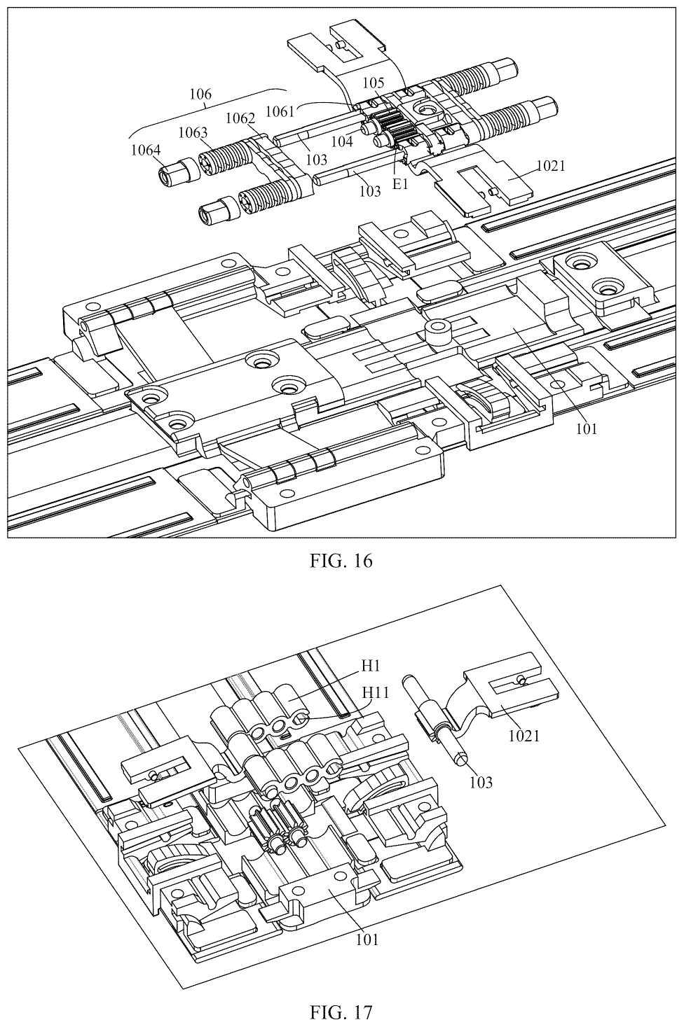

Optionally, reference is made to FIG. 16, which is a partially exploded schematic diagram of a structure of a first flip mechanism according to an embodiment of the present disclosure. In order to ensure that two first flip assemblies 102 in a group of first flip mechanisms 100 can move in synchronization during the folding or unfolding of the hinge, the present disclosure provides a synchronizing mechanism which can achieve synchronous opposite rotation and synchronous departure rotation between the two first flip assemblies. The group of first flip mechanisms 100 may further include: two first synchronizing shafts 103, and the two first synchronizing shafts 103 may be both fixed within the first support base 101, and each of the two first synchronizing shafts 103 may be rotatably connected to one end of each of the two first swing arms 1021 in the two first flip assemblies 102. In the present disclosure, the group of first flip mechanisms 100 may further include: two second synchronizing shafts 104 disposed between the two first synchronizing shafts 103, and two first synchronous gears 105, each of which is sleeved on each of the second synchronizing shafts 104. The two first synchronous gears 105 on the two second synchronizing shafts 104 engage. One end of the first swing arm 1021 may have a plurality of first external teeth E1 engaged with the first synchronous gears 105. Exemplarily, when a first swing arm 1021 is rotated counterclockwise, the first swing arm 1021 also drives the first external teeth E1 to rotate counterclockwise; then the first external teeth E1 drives a first synchronous gear 105 on one second synchronizing shaft 104 to rotate clockwise; and thereafter the first synchronous gear 105 on the first synchronizing shaft 104 drives a first synchronous gear 105 on another second synchronizing shaft 104 to rotate counterclockwise. Afterwards, the first synchronous gear 105 on the another second synchronizing shaft 104 drives the plurality of first external teeth E1 on another first swing arm 1021 to rotate clockwise. In this way, it is possible to achieve the synchronous rotation of the two first flip assemblies 102 through the cooperation of the synchronizing shafts and the synchronizing gears, which improves the user's sense of experience. In the present disclosure, the at least one group of first flip mechanisms 100 may include two groups of synchronizing mechanisms (including synchronizing shafts and synchronizing gears), and the two groups of synchronizing mechanisms may be located on both sides of the first flip mechanism, thereby further ensuring better synchronization of the first flip assemblies in the first flip mechanism in the foldable display device.

In the present disclosure, the two second synchronizing shafts 104 may be disposed within the first support base 101 and rotatably connected to the first support base 101, and the first synchronous gear 105 is sleeved on the second synchronizing shaft 104 and fixedly connected to the second synchronizing shaft 104; alternatively, the two second synchronizing shafts 104 may be disposed within the first support base 101 and fixedly connected to the first support base 101, and the first synchronous gear 105 is sleeved on the second synchronizing shaft 104 and rotatably connected to the second synchronizing shaft 104.

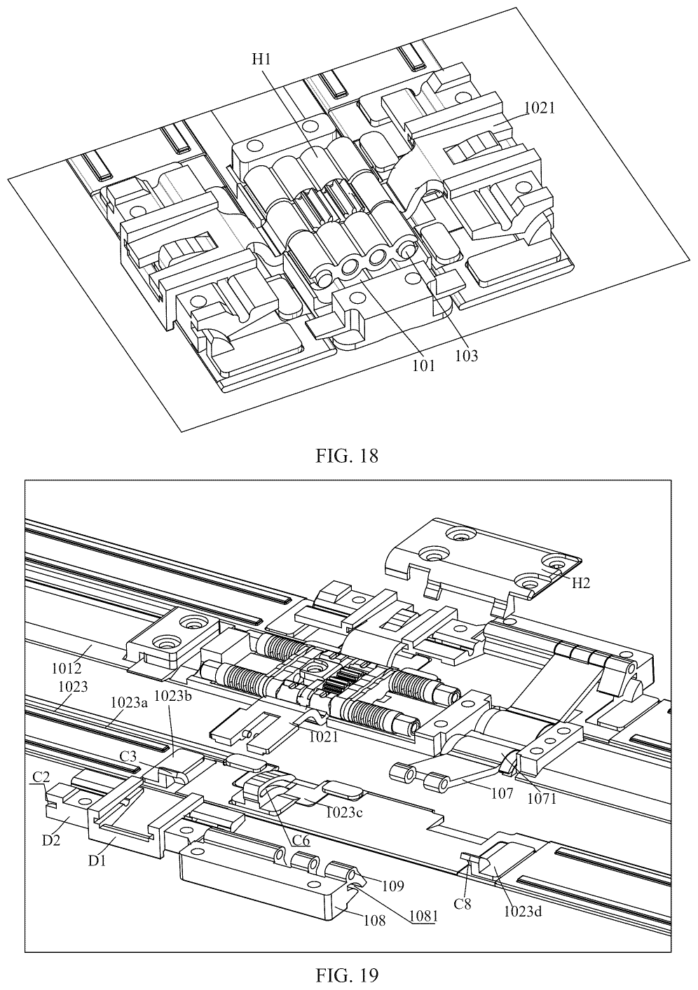

It should be noted that the two first synchronizing shafts 103 may also be disposed within the first support base 101, and both are rotatably connected to the first support base 101. Each of the two first synchronizing shafts 103 may be fixedly connected to one end of each of the two first swing arms 1021 in the two first flip assemblies 102, which is not specifically limited by embodiments of the present disclosure. For example, reference is made to FIG. 17 and FIG. 18. FIG. 17 is an exploded schematic diagram of part of a structure of another first flip mechanism according to an embodiment of the present disclosure, and FIG. 18 is a schematic diagram of the assembly of the first flip mechanism shown in FIG. 17. The first synchronizing shaft 103 may be disposed within the first support base 101 and rotatably connected to the first support base 101. One end of the first swing arm 1021 is fixedly connected to the first synchronizing shaft 103. Exemplarily, the first support base 101 is provided with a first base H1, the first base Hl has a plurality of shaft holes H11, and the first synchronizing shaft 103 is disposed within the shaft hole H11 and rotatably connected with the first base H1. It should be noted that the description of other structures connected to the first swing arm 1021 can be referred to the relevant descriptions in the above embodiments and will not be repeated herein.

In practice, when the hinges are in the process of folding or unfolding, in order to provide them with a certain damping effect or a self-hovering ability, as shown in FIG. 16, the group of first flip mechanisms 100 may also include: first torsion assemblies 106 each of which is connected to each of the first synchronizing shafts 103, and is configured to: provide a damping force when the two first flipping assemblies 102 are rotated relative to the first support base 101. In the present disclosure, the number of first torsion assemblies 106 connected to the two first synchronizing shafts 103 is two. Taking one first torsion assembly as an example, the first torsion assembly 106 may include: a first movable cam 1061 sleeved on the first synchronizing shaft 103, a first fixed cam 1062, a first elastic element 1063, and a first locking member 1064. The first movable cam 1061 may be fixedly connected to a side of the first swing arm 1021, the first fixed cam 1062 may be located on a side of the first movable cam 1061 away from the first swing arm 1021, the first locking member 1064 may be located on a side of the first fixed cam 1062 away from the first movable cam 1061 and may be fixedly connected to the first synchronizing shaft 103. The first elastic element 1063 may be disposed between the first fixed cam 1062 and the first locking member 1064. Exemplarily, the first movable cam 1061 can be rotated when the first swing arm 1021 is rotated; then, the first movable cam 1061 can be rotated relative to the first fixed cam 1062, and when a projecting portion (not shown in the figure) of the first movable cam 1061 tends to slide out of a recessed portion of the first fixed cam 1062, the first elastic element 1063 is compressed so that a certain damping force can be provided by the first torsion assembly 106. provide a certain damping force. When the projection portion of the first movable cam 1061 is located in the recessed portion of the first fixed cam 1062, the first elastic element 1063 enables the first fixed cam 1062 and the first movable cam 1061 to remain relatively stationary. In this way, a self-hovering effect of the foldable display device can be realized by the first torsion assembly 106.

For example, when the hinge is in the fully unfolded state, the projecting portion of the first fixed cam 1062 (not shown in the figure) may be precisely located within the recessed portion of the first movable cam 1061 (not shown in the figure) to enable the hinge to maintain that particular angle, so that when the user is touching or pressing the flexible screen, the foldable display device will not be easily folded under the action of an external force. When the hinge is in the fully folded state, the projecting portion of the first fixed cam 1062 may be located just inside the recessed portion of the first movable cam 1061 to enable the hinge to maintain that particular angle. When the user is touching or pressing the flexible screen, the foldable display device will not be unfolded arbitrarily under the action of an external force, thereby ensuring the safety of the display device. It should be noted that the two first torsion assemblies 106 have the same movement principle, which can be referred to the above relevant description for the first torsion assembly, and will not be repeated herein. In the present disclosure, the first movable cam 1061 and the first fixed cam 1062 may be friction plates in contact with each other, and the hovering is realized by the friction effect between the friction plates. Optionally, the first elastic elements 1063 may all include a plurality of laminated disc springs. It is to be noted that in other possible implementation, the first elastic element 1063 may also be a compression spring or a spring leaf, and the embodiments of the present disclosure do not specifically limit this.

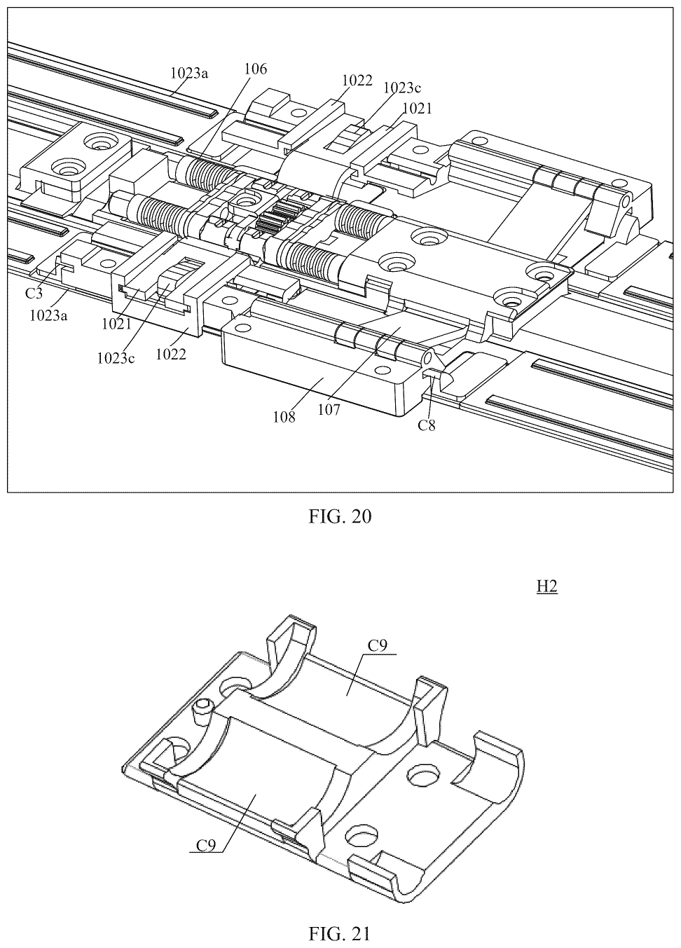

Optionally, please refer to FIG. 19 and FIG. 20. FIG. 19 is an exploded schematic diagram of yet another first flip mechanism according to an embodiment of the present disclosure, and FIG. 20 is a schematic diagram of an assembly of the first flip mechanism shown in FIG. 19. The first flip assembly 102 in the first flip mechanism 100 may further include: a second swing arm 107 and a second adapter fixing member 108. One end of the second swing arm 107 may be rotatably connected to the first support base 101, the other end of the second swing arm 107 may be rotatably connected to the second adapter fixing member 108, and the second adapter fixing member 108 may be rotatably connected to the first flip plate 1023. The second adapter fixing member 108 may be used to fixedly connect to a housing in the foldable display device. Exemplarily, when the hinge is switched between the folded state and the unfolded state, the second adapter fixing member 108 is rotated in one direction under the action of an external force, at this time, the second adapter fixing member 108 will drive the second swing arm 107 to rotate in the same direction. In the process of rotation, the second adapter fixing member 108 can swing around the other end of the second swing arm 107, which enables the length of the linkage mechanism formed by the second adapter fixing member 108 and the second swing arm 107 to be varied. When the first adapter fixing member 1022 connected to the housing in the foldable display device has a degree of freedom to move away from the first support plate 1012, the cooperation of the second swing arm 107 and the second adapter fixing member 108 prevents the first adapter fixing member 1022 from moving too far away from the first support base 101. It is to be noted that the two first flip assemblies 102 are symmetrically provided relative to the first support base 101, and the basic structural composition and movement principle of the other first flip assembly 102 may be the same as that of the first flip assembly described above. Therefore, in the embodiment of the present disclosure, the structural composition and movement principle of the other first flip assembly can be referred to the above description of the first flip assembly, and will not be repeated herein. In the present disclosure, the first flip assembly 102 may further include: a first connecting shaft 109 fixed to the side of the second adapter fixing member 108 away from the flexible display panel, and one end of the second swing arm 107 away from the first support base 101 may be rotatably connected with the first connecting shaft 109. In this case, the end of the second swing arm 107 away from the first support base 101 is rotatably connected with the first connection shaft 109, so that the rotating connection between the second swing arm 107 and the second adapter fixing member 108 can be realized.

In embodiments of the present disclosure, as in FIGS. 19 and 20, at least one side of the second adapter fixing member 108 may have a fourth arc-shaped slide groove 1081. The first flip plate 1023 may further include: a fourth slide member 1023d fixedly connected to the side of the first flip plate body 1023a away from the flexible display panel, and at least a portion of the fourth slide member 1023d may be disposed within the fourth arc-shaped slide groove 1081. In the present disclosure, the fourth slide member 1023d may have a second arc-shaped slide block C8 that cooperates with the fourth arc-shaped slide groove 1081, the second arc-shaped slide block C8 can slide within the fourth arc-shaped slide groove 1081.

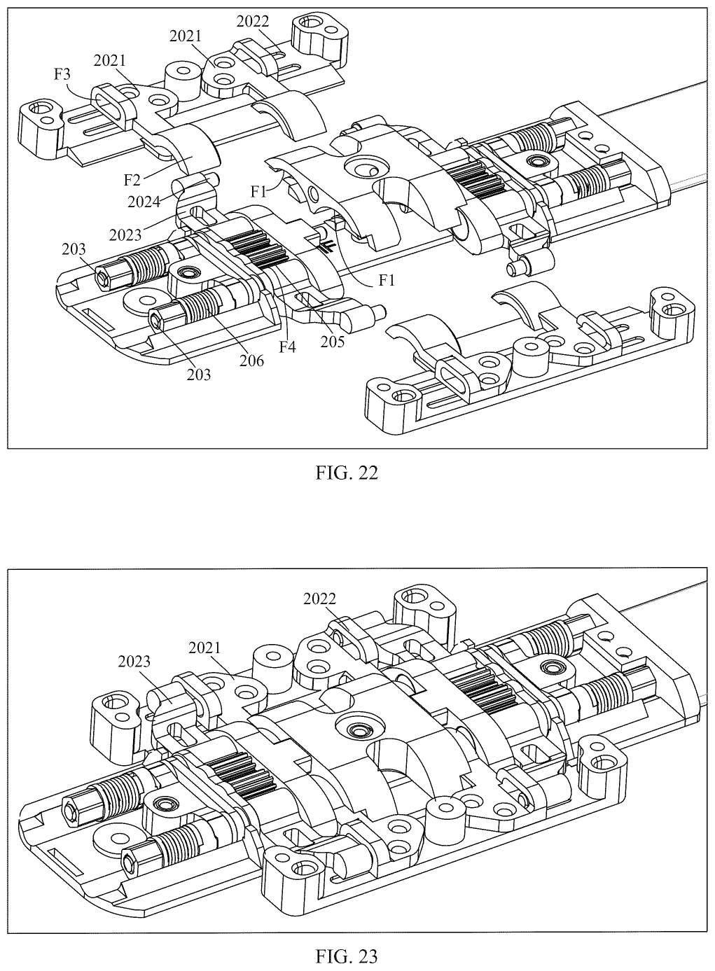

Optionally, as in FIGS. 19 and 20, the first support base 101 may have a fifth arc-shaped slide groove (shown in subsequent FIG. 21), and one end of the second swing arm 107 may have a fifth slide member 1071 that cooperates with the fifth arc-shaped slide groove, and at least a portion of the fifth slide member 1071 may be disposed within the fifth arc-shaped slide groove. In this case, the fifth arc-shaped slide groove is arranged in the first support base 101, and one end of the second swing arm 107 is provided with the fifth slide member 1071, so that the rotating connection between the end of the second swing arm 107 and the first support base 101 can be conveniently realized by the cooperative sliding between the fifth slide member 1071 and the fifth arc-shaped slide groove. For example, please refer to FIG. 19 and FIG. 21. FIG. 21 is a schematic diagram of a structure of a second base according to an embodiment of the present disclosure. The first support base 101 can include a second base H2, one side of the second base H2 is fixed to the first support plate 1012, and a fifth arc-shaped slide groove C9 may be disposed in the second base H2.

In an embodiment of the present disclosure, the first rotation fixing member 1022 and the second adapter fixing member 108 in the first flip assembly 102 may be a one-piece structure, as shown in FIG. 20. In the present disclosure, in the first flip assembly 102, a rotating shaft formed by an associated structure connected to the first swing arm 1021 may be referred to as a countershaft, as shown in FIGS. 17 and 18; a rotating shaft formed by an associated structure connected to the second swing arm 107 may be referred to as a virtual shaft, as shown in FIGS. 10 and 20; a rotating shaft formed by the associated structure connected to the first swing arm 1021 and the associated structure connected to the second swing arm 107 may be referred to as a main shaft, as shown in FIG. 10 and FIG. 20. The main shaft, the countershaft and the virtual shaft may be arranged arbitrarily along the first direction f1, and the number of main shaft, countershaft and virtual shaft may be set according to the actual needs, and the embodiments of the present disclosure do not make any specific limitations in this regard. For example, in at least two groups of first flip mechanisms 100, two main shafts and one countershaft may be distributed on one side of the transition mechanism, and one virtual shaft and one countershaft may be distributed on the other side of the transition mechanism.

The following embodiments schematically illustrate a second flip mechanism 200 in a foldable display device. Please refer to FIG. 22 and FIG. 23. FIG. 22 is an exploded schematic diagram of part of a structure of a second flip mechanism according to an embodiment of the present disclosure, and FIG. 23 is a schematic diagram of an assembly of the second flip mechanism shown in FIG. 22. The second flipping assembly 202 in the second flip mechanism 200 may include: a first drive rod 2021 and a second flip plate 2022. One end of the first drive rod 2021 may be rotatably connected to the second support base 201, and the other end of the first drive rod 2021 may be fixedly connected to the second flip plate 2022. The second flip plate 2022 may be used for connecting with the housing in the foldable display device, and one side of the second flip plate 2022 is used to abut against a back of the flexible display panel in the foldable display device. The first axis may be at the side of the second support base 201 close to the flexible display pane, around which one end of the first drive rod 2021 is rotated relative to the second support base 201. There is a distance between the first axis and the second support base 201. Exemplarily, when the hinge is switched from the unfolded state to the folded state, the second flip plate 2022 may rotate counterclockwise under the action of an external force, and at this time, the second flip plate 2022 drives the first drive rod 2021 to rotate counterclockwise. During rotation, the flexible display panel usually has a tendency to stretch, and the second flip plate 2022 connected to the housing in the foldable display device can have a degree of freedom to move away from the second support plate 2012, so that the housing can cooperate with the movement tendency of the flexible display panel to ensure that the housing will not have a pulling phenomenon on the flexible display panel. In this case, the hinge is in the shape of a “U-shape”, also known as a U-shaped hinge. When the hinge is switched from the folded state to the unfolded state, under the action of an external force, the second flip plate 2022, which is fixedly connected to the housing in the foldable display device, rotates clockwise, and at this time, the second flip plate 2022 can drive the first drive rod 2021 to rotate clockwise. During rotation, the flexible display panel usually exhibits a tendency to contract, and the second flip plate 2022 connected to the housing in the foldable display device can have a degree of freedom to move close to the second support plate 2012, so that the housing can cooperate with the tendency of the movement of the flexible display panel to ensure that the housing will not produce a pulling phenomenon on the flexible display panel. In addition, as the hinge is unfolded to the final state (i.e., the angle between the two second flip plates 2022 in the two second flip assemblies 202 is 180 degrees), surfaces of the two second flip plates 2022 in the two second flip assemblies 202 close to the flexible display panel are co-planar, i.e., the surfaces of the two second flip plates 2022 in the two second flip assemblies 202 close to the flexible display panel can form a flat support surface, and thus can provide good support for the flexible screen. Exemplarily, as shown in FIG. 2, the number of groups of second flip mechanisms 200 may be four. Two groups of second flip mechanisms are located on one side of the transition mechanism 300, and the other two groups of second flip mechanisms are located on the other side of the transition mechanism 300.

Optionally, as shown in FIG. 22, the second support base 201 in the second flip mechanism 200 may have a sixth arc-shaped slide groove F1, one end of the first drive rod 2021 may have a sixth slide member F2 that cooperates with the sixth arc-shaped slide groove F1, and at least a portion of the sixth slide member F2 may be disposed within the sixth arc-shaped slide groove F1 in the second support base 201. In this case, the sixth arc-shaped slide groove F1 is arranged in the second support base 201 and the sixth slide member F2 is arranged at one end of the first drive rod 2021, the rotating connection between the one end of the first drive rod 2021 and the second support base 201 can be conveniently realized through the cooperation of the sixth slide member F2 with the sixth arc-shaped slide groove F1.

In an embodiment of the present disclosure, as shown in FIGS. 22 and 23, the second flip assembly 202 may further include: a second drive rod 2023 and a second connecting shaft 2024. One end of the second drive rod 2023 may be rotatably connected to the second support base 201, and the other end of the second drive rod 2023 may be fixedly connected to one end of the second connecting shaft 2024. One end of the first drive rod 2021 away from the second support base 201 may have a second straight slide groove F3, and the other end of the second connecting shaft 2024 may be slidably connected to the first drive rod 2021 within the second straight slide groove F3 in the first drive rod 2021. A second axis of the second drive rod 2023 around which one end of the second drive rod 2023 is rotated relative to the second support base 201 may be located within the second support base 201, and the second axis may be parallel to the first axis and parallel to an axis of the second connecting shaft 2024. In this case, the second drive rod 2023 is rotatably connected to the second support base 201 and the second connecting shaft 2024 is fixed at the other end of the second drive rod 2023, so that the second drive rod 2023 can be driven to rotate in the process of rotation of the first drive rod 2021, and the second connecting shaft 2024 can be limited to one end of the second straight slide groove F3 when the first drive rod 2021 is rotated to a certain angle, thereby limiting the rotation of the first drive rod 2021.

Optionally, in order to ensure that the two second flip assemblies 202 in the group of second flip mechanisms 200 can move synchronously during the folding or unfolding process of the hinge, as shown in FIG. 22, the present disclosure provides a synchronizing mechanism which can realize synchronous opposite rotation and synchronous departure rotation between the two second flip assemblies. The group of second flip mechanisms 200 may further include: two third synchronizing shafts 203, the two third synchronizing shafts 203 may be both fixed within the second support base 201, and each of the two third synchronizing shafts 203 may be rotatably connected to one end of each of the two second drive rods 2023 in the two second flip assemblies 202. In the present disclosure, the group of second flip mechanisms 200 may further include: two fourth synchronizing shafts (not shown in the figure) disposed between the two third synchronizing shafts 203, and two second synchronizing gears 205 each of which is sleeved on each of the fourth synchronizing shafts. The two second synchronizing gears 205 on the two fourth synchronizing shafts engage, and one end of the second drive rods 2023 may have a plurality of second outer teeth F4 engaging with the second synchronizing gears 205. Exemplarily, when one second drive rod 2023 rotates counterclockwise, the second drive rod 2023 also drives the second outer teeth F4 to rotate counterclockwise; then, the second outer teeth F4 drive the second synchronizing gear 205 on one fourth synchronizing shaft to rotate clockwise; thereafter, the second synchronizing gear 205 on one fourth synchronizing shaft drives one second synchronizing gear 205 on another fourth synchronizing shaft to rotate counterclockwise. Afterwards, the second synchronizing gear 205 on the another fourth synchronizing shaft drives the plurality of second outer teeth F4 on the other second drive rod 2023 to rotate clockwise. In this way, the synchronized rotation of the two second flip assemblies can be achieved through the cooperation of the synchronizing shaft and the synchronizing gear, which improves the user's sense of experience. In the present disclosure, the at least one group of second flip mechanisms may include two groups of synchronizing mechanisms (including the synchronization shaft and the synchronization gear), and the two groups of synchronizing mechanisms may be located on both sides of this group of second flip mechanisms 200, which further ensures a better synchronization of the second flip assemblies in the second flip mechanisms in the foldable display device. In the present disclosure, the two fourth synchronizing shafts 204 may be disposed within the second support base 201 and rotatably connected to the second support base 201, and the second synchronizing gears 205 are sleeved on the fourth synchronizing shafts and fixedly connected to the fourth synchronizing shafts; alternatively, the two fourth synchronizing shafts may be disposed within the second support base 201 and fixedly connected to the second support base 201, and the second synchronizing gears 205 are sleeved on the fourth synchronizing shafts are rotatably connected to the fourth synchronizing shafts.

In practice, when the hinge is in the process of folding or unfolding, in order to provide it with a certain damping effect or self-hovering ability, as shown in FIG. 22, the group of second flip mechanisms 200 may also include: a second torsion assembly 206 connected to each of the third synchronizing shafts 203. The second torsion assembly 206 may be configured to provide a damping force when the two second flipping assemblies 202 are rotated relative to the second support base 201. A self-hovering effect of the foldable display device can be realized by the second torsion assembly 206. It should be noted that the structure and functioning principle of the second torsion assembly 206 can be referred to the structure and functioning principle of the first torsion assembly 106.

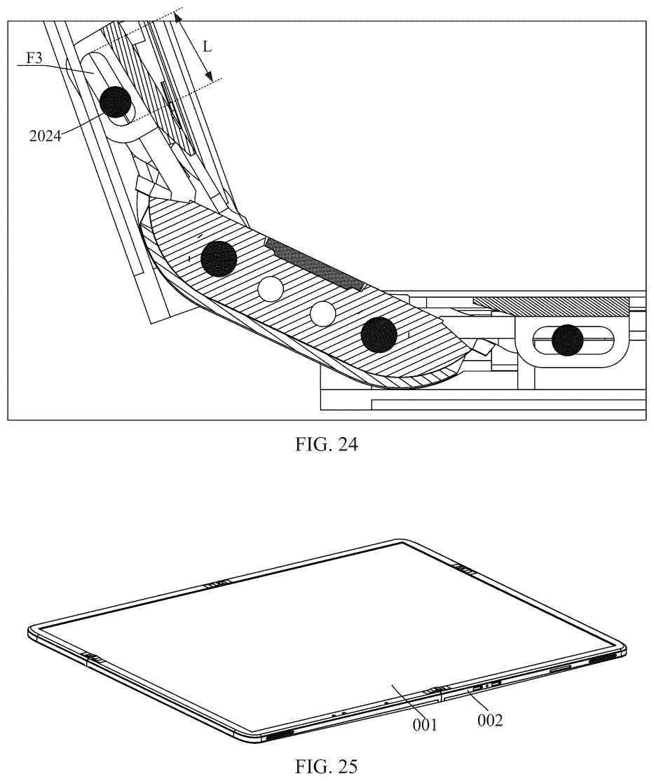

Optionally, reference is made to FIG. 24, which is a sectional view of a second drive rod connected to a first drive rod in a second flip assembly according to an embodiment of the present disclosure. The length L of the second straight slide groove F3 in the first drive rod 2021 may be greater than 0 and less than or equal to 3 millimeters, for example, it may be 1.5 millimeters, 2 millimeters, or it may be 2.95 millimeters, etc., and the embodiments of the present disclosure do not make specific limitations in this regard. In this way, the length of the second straight slide groove F3 in the first drive rod 2021 is set to be within the range, when the first drive rod 2021 rotates to a certain angle, the second connecting shaft 2024, which is fixedly connected to the second drive rod 2023, can abut against one end of the second straight slide groove F3. In the present disclosure, a maximum rotation angle of the first flip assembly 102 in the hinge relative to the first support base 101 may be greater than or equal to 90 degrees, for example, the maximum angle of rotation may be 98 degrees, 100 degrees, or 103 degrees, etc., and the embodiments of the present disclosure do not make specific limitations in this regard. A maximum rotation angle of the second flip assembly 202 in the hinge relative to the second support base 201 is less than or equal to 45 degrees, for example, the maximum rotation angle may be 20 degrees, 30 degrees, or 40 degrees, etc., and the embodiments of the present disclosure do not make specific limitations thereon.

In an embodiment of the present disclosure, as shown in FIG. 2, one first support base 101 in each group of first flip mechanisms 100 located on one side of the transition mechanism 300 is of one-piece structure, and one first support base 101 in each group of first flip mechanisms 100 located on the other side of the transition mechanism 300 may be of one-piece structure. In the first direction f1, a length of the first support base 101 located on one side of the transition mechanism 300 may be greater than a length of the first support base 101 located on the other side of the transition mechanism 300. One second support base 201 in each group of second flip mechanisms 200 located on one side of the transition mechanism 300 is a one-piece structure, and the second support base 201 in each group of second flip mechanisms 200 located on the other side of the transition mechanism 300 may be a one-piece structure. In the second direction f2, a length of the second support base 201 located on one side of the transition mechanism 300 may be equal to a length of a second support base 201 located on the other side of the transition mechanism 300. In this way, after the foldable display device is folded by the second flip mechanism 200, areas of the portions of the flexible display panel in the foldable display device disposed on both sides of the second flip mechanism 200 are different, thereby bringing a different sense of using experience. It is to be noted that in other possible implementation, in the first direction f1, the length of the first support base 101 disposed on one side of the transition mechanism 300 may be equal to the length of the first support base 101 disposed on the other side of the transition mechanism 300. In addition, after the foldable display device is folded by the first flip mechanism 100, areas of the portions of the flexible display panel in the foldable display device disposed on both sides of the first flip mechanism 100 are the same, bringing a different sense of using experience. It is to be noted that in other possible implementation, in the second direction f2, the length of the second support base 201 disposed on one side of the transition mechanism 300 may be greater than the length of the second support base 201 disposed on the other side of the transition mechanism 300.

In the present disclosure, the first support base 101 in each group of first flip mechanisms 100 located on one side of the transition mechanism 300 may be a one-piece structure. That is, the first support base body 1011 in the first support base 101 may be a one-piece structure, and the first support plate 1012 in the first support base 101 may also be a one-piece structure. It is to be noted that when a distance between two groups of adjacent first flip mechanisms 100 is large, one group of first flip mechanisms 100 correspondingly may correspond to one section of the first support plate 1012 and the two first support plates 1012 may be connected to each other by a first auxiliary support plate (not shown in the figure), and ends of the first auxiliary support plate may be fixedly connected to the two sections of the first support plates 1012 respectively. For the first support base 101 in each group of first flip mechanisms 100 located on the other side of the transition mechanism 300 may be a one-piece structure. That is, the first support base body 1011 in the first support base 101 may be a one-piece structure, and the first support plate 1012 in the first support base 101 may also be a one-piece structure. It is to be noted that when a distance between two groups of adjacent first flip mechanisms 100 is large, one group of first flip mechanisms 100 may correspond to one section of the first support plate 1012 and the two first support plates 1012 may be connected by a first auxiliary support plate, and the two ends of the first auxiliary support plate may be fixedly connected to the two sections of the first support plate respectively.

In the present disclosure, the second support base 201 in each group of second flip mechanisms 200 located on one side of the transition mechanism 300 may be a one-piece structure. That is, the second support base body 2011 in the second support base 201 may be a one-piece structure, and the second support plate 2012 in the second support base 201 may be a one-piece structure. It is to be noted that when a distance between two groups of adjacent second flip mechanisms 200 is large, one group of second flip mechanism correspondences may correspond to one section of the second support plate 2012 and the two second support plates 2012 may be connected with a second auxiliary support plate (not shown in the figure), and two ends of the second auxiliary support plate may be fixedly connected with two sections of the second support plates 2012 respectively. For the second support base 201 in each group of second flip mechanisms 200 located on the other side of the transition mechanism 300 may be of one-piece structure. That is, the second support base body 2011 in the second support base 201 may be a one-piece structure, and the second support plate 2012 in the second support base 201 may be a one-piece structure. It is to be noted that when a distance between two groups of adjacent second flip mechanisms 200 is large, one group of second flip mechanisms 200 may correspond to one section of the second support plate 2012 and the two second support plates 2012 may be connected by a second auxiliary support plate, and the two ends of the second auxiliary support plate may be fixedly connected to the two sections of the second support plate 2012 respectively.

It should be noted that in the present disclosure, the structure of the first flip mechanism 100 distributed along the first direction f1 may be the same as the structure of the second flip mechanism 200 distributed along the second direction f2. For example, the structure of the first flip mechanism 100 and the structure of the second flip mechanism 200 can be both the same as the structure of the first flip mechanism in the above embodiment (i.e., both directions can be folded to form a “water drop” shape); or the structure of the first flip mechanism 100 and the structure of the second flip mechanism 200 can be both the same as the structure of the second flip mechanism in the above embodiment (i.e., a “U” shape may be formed after folding in both directions); or one of the structure of the first flip mechanism 100 distributed along the first direction f1 and the structure of the second flip mechanism 200 distributed along the second direction f2 may be folded to form a “water drop” shape and the other one may be folded to form a “U” shape.

In summary, embodiments of the present disclosure provide a hinge that may include: at least two groups of first flip mechanisms, at least two groups of second flip mechanisms, and a transition mechanism. Since the at least two groups of first flip mechanisms, the at least two groups of second flip mechanisms and the transition mechanism are provided in the hinge, there are two groups of first flip mechanisms distributed on both sides of the transition mechanism and rotatably connected to the transition mechanism, and there are two groups of second flip mechanisms distributed on both sides of the transition mechanism and provided separately from the transition mechanism. Thus, the folding or unfolding of the foldable display device around a first direction can be achieved by the first flip mechanism, and the folding or unfolding of the foldable display device around a second direction can be realized by the second flip mechanism. In other words, the foldable display device can be folded or unfolded in two directions, which effectively improves the flexibility of the use of the foldable display device.

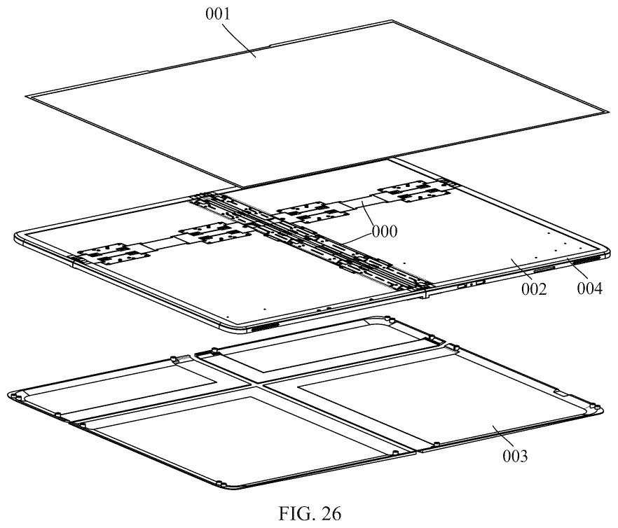

Embodiments of the present disclosure also provide a foldable display device, and please refer to FIG. 25 and FIG. 26. FIG. 25 is a schematic view of a structure of a foldable display device according to an embodiment of the present disclosure, and FIG. 26 is an exploded schematic view of the foldable display device shown in FIG. 25. The foldable display device may include: a flexible display panel 001, a housing 002, and a hinge 000. The housing 002 may be fixedly connected to a back of the flexible display panel 001, and may be fixedly connected to the hinge 000. The hinge 000 may be a hinge as given in any of the above. In this way, since at least two groups of first flip mechanisms 100, at least two groups of second flip mechanisms 200, and the transition mechanism 300 are provided in the hinge 000, there are two groups of first flip mechanisms 100 distributed on both sides of the transition mechanism 300 and rotatably connected with the transition mechanism 300, and there are two groups of second flip mechanisms 200 distributed on both sides of the transition mechanism 300 and provided separately from the transition mechanism 300. Therefore, the first flip mechanism 100 can realize the folding or unfolding of the foldable display device in a first direction, and the second flip mechanism 200 can realize the folding or unfolding of the foldable display device in a second direction. In other words, the foldable display device can be folded or unfolded in two directions, which effectively improves the flexibility of the use of the foldable display device.

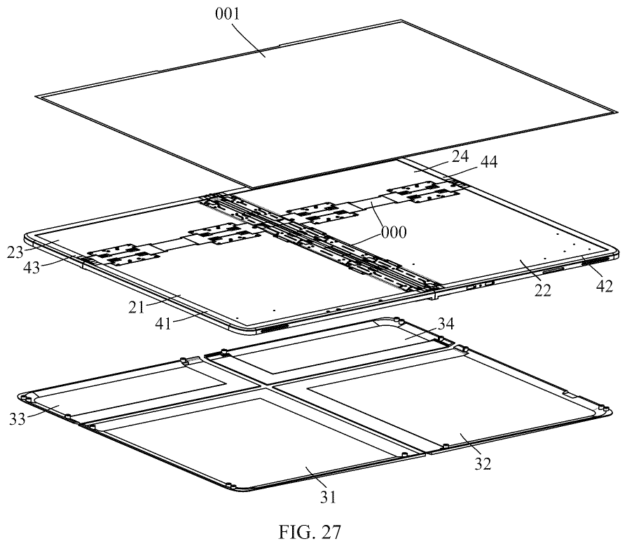

Optionally, reference is made to FIG. 26 and FIG. 27. FIG. 27 is an exploded schematic view of another structure of the foldable display device shown in FIG. 25. The housing 002 in the foldable display device may include: a first housing 21, a second housing 22, a third housing 23, and a fourth housing 24 disposed separately. The first housing 21 may be connected to the second housing 22 by at least one group of first flip mechanisms 100 disposed on one side of the transition mechanism 300. The third shell 23 may be connected to the fourth shell 24 via the at least one group of first flip mechanisms 100 disposed on the other side of the transition mechanism 300. The first housing 21 and the third housing 23 may be connected to each other by at least one group of second flip mechanisms 200 located on one side of the transition mechanism 300. The second housing 22 and the fourth housing 24 may be connected to each other via the at least one group of second flip mechanisms 200 located on the other side of the transition mechanism 300.

In embodiments of the present disclosure, as in FIGS. 26 and 27, the foldable display device may further include: a back cover 003 snapped to the side of the housing 002 away from the flexible display panel 001. In this way, the back of the housing 002 in the foldable display device can be decorated by the back cover 003. Exemplarily, the rear cover 003 may include: a first cover body 31, a second cover body 32, a third cover body 33, and a fourth cover body 34 provided separately. The first cover body 31 may be secured to the back of the first housing 21, the second cover body 32 may be secured to the back of the second housing 22, the third cover body 33 may be secured to the back of the third housing 23, and the fourth cover body 34 may be secured to the back of the fourth housing 24. In the present disclosure, the foldable display device may further include: a bezel 004 enclosing an edge of the housing 002, such that the edge of the housing 002 in the foldable display device can be decorated by the bezel 004. Exemplarily, the bezel 004 may include: a first frame 41, a second frame 42, a third frame 43, and a fourth frame 44 provided separately. The first frame 41 may be secured to an edge of the first housing 21, the second frame 42 may be secured to an edge of the second housing 22, the third frame 43 may be secured to an edge of the third housing 23, and the fourth frame 44 may be secured to an edge of the fourth housing 24.

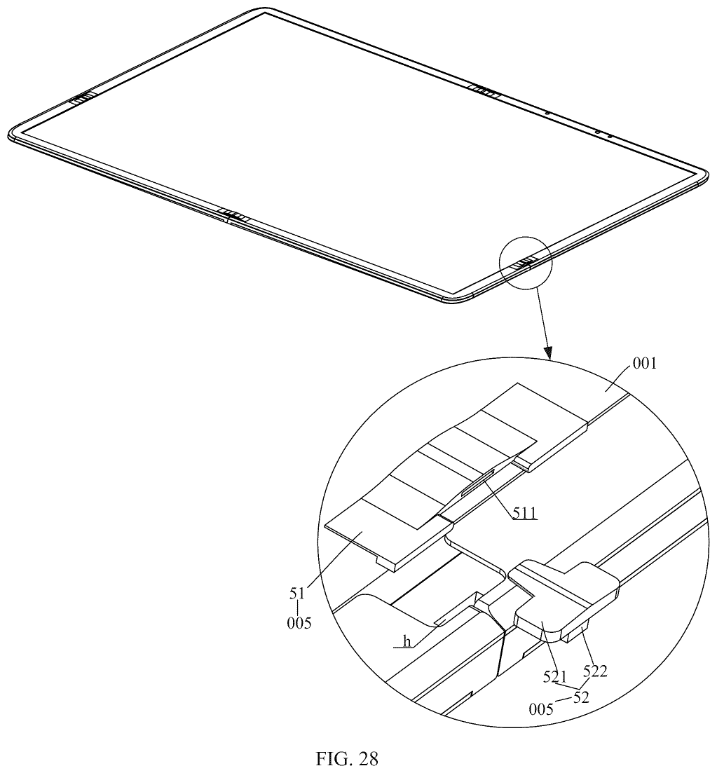

In the present disclosure, reference is made to FIG. 28, which is a schematic diagram of a structure of another foldable display device provided by embodiments of the present disclosure. The foldable display device may further include: a connection assembly 005. The first flip mechanism and the second flip mechanism are disposed on the back of the flexible display panel, and the connection assembly 005 connects the flexible display panel 001 to the first flip mechanism 100 and/or the second flip mechanism 200. Exemplarily, the connection assembly 005 may include a flexible fixing member 51 and a locking member 52. The flexible fixing member 51 is disposed on the front side of an edge of the flexible display panel 001, for example, the flexible fixing member 51 may be in contact with the edge of the flexible display panel 001 and is not in contact with a display area of the flexible display panel 001. The flexible fixing member 51 is disposed at one end of a folding axis of the flexible display panel 001 and is across the folding axis (exemplarily, there are two intersecting folding axes of the flexible display panel). One of the folding axes of the flexible display panel 001 may be directly opposite the first support panel 1012 (e.g., directly opposite a centerline of the first support panel); and the other folding axis of the flexible display panel 001 may be directly opposite the second support panel 2012 (e.g., directly opposite a centerline of the second support panel). A fixing portion 511 is provided on the flexible fixing member 51 opposite the folding axis, for example, the fixing portion 511 may be a connection hole. The connection hole is directly opposite the first support plate 1012 (e.g. a centerline of the connection hole is directly opposite a centerline of the first support plate). The locking member 52 includes a first connecting portion 521 and a second connecting portion 522 connected to each other, and the first connecting portion 521 is connected to the fixing portion 511, e.g. the first connecting portion 521 is inserted in the connecting hole, and thus the portion of the flexible fixing member 51 that is directly opposite the first support plate is prevented from arching. The second connection portion 522 is fixedly connected to the first support plate 1012 in the first flip mechanism; for example, the second connection portion 522 may be inserted within the slot h of the first support plate 1012 and glued. The material of the flexible fixing member 51 is an impact-resistant flexible material, such as rubber (e.g., thermoplastic polyurethane rubber) or the like. The first connection portion 521 and the second connection portion 522 may be integrally provided. The material of the first connection portion 521 and the second connection portion 522 may be a metallic material, such as aluminum, iron, etc. In the present disclosure, the number of connection assemblies 005 may be four, two connection assemblies 005 are distributed at the two end portions of the first support plate 1012 along the first direction f1; and the other two connection assemblies 005 are distributed at the two end portions of the second support plate 2012 along the second direction f2.

In some examples, a gap of 0.2 mm to 0.5 mm (e.g., 0.2 mm, 0.3 mm, 0.4 mm, 0.5 mm, etc.) exists between the flexible fixing member 51 and the flexible display panel 001, which can prevent the flexible fixing member 51 from crushing the flexible display panel. For example, the gap can be filled with cushioning foam, which can reduce the swaying of the flexible display panel.

It is noted that in the accompanying drawings, the dimensions of the layers and regions may be exaggerated for the sake of clarity of illustration. Moreover, it is understood that when an element or layer is referred to as being “on” another element or layer, it may be directly on the other element or there may be intervening layers. Also, it can be understood that when the element or layer is referred to as being “under” another element or layer, it can be directly under the other element, or more than one intermediate layer or element can exist. It is also understood that when a layer or element is referred to as being “between” two layers or elements, it may be the only layer between the two layers or elements, or there may be more than one intermediate layer or element. Similar reference marks throughout indicate similar elements.

In the present disclosure, the terms “first” and “second” are used for descriptive purposes only and are not to be understood as indicating or implying relative importance. The term “plurality” refers to two or more, unless otherwise expressly limited.

The foregoing are only optional embodiments of this application and are not intended to limit this application, and any modifications, equivalent substitutions, improvements, etc., made within the spirit and principles of this application shall be included in the scope of protection of this application.

1. A hinge, comprising:
at least two groups of first flip mechanisms, wherein one group of the at least two groups of first flip mechanisms comprises a first support base extending in a first direction and two first flip assemblies which are rotatably connected to the first support base and are oppositely arranged;
at least two groups of second flip mechanisms, wherein one group of the at least two groups of second flip mechanisms comprises a second support base extending in a second direction and two second flip assemblies which are rotatably connected to the second support base set and are oppositely arranged; and
a transition mechanism, wherein two groups of the at least two groups of first flip mechanisms are arranged on both sides of the transition mechanism in the first direction and are both rotatably connected to the transition mechanism; and two groups of the at least two groups of second flip mechanisms are arranged on both sides of the transition mechanism in the second direction and are both arranged separately from the transition mechanism;
wherein the first direction is intersected with the second direction.

2. The hinge according to claim 1, wherein a first slide member is arranged at an end of the first support base close to the transition mechanism, the transition mechanism comprises a first arc-shaped slide groove in cooperation with the first slide member, and at least a portion of the first slide member is within the first arc-shaped slide groove.

3. The hinge according to claim 2, wherein the transition mechanism comprises a first transition member and a second transition member fixedly connected to a side of the first transition member, and the first arc-shaped slide groove is between the first transition member and the second transition.

4. The hinge according to claim 3, wherein the first slide member comprises a first slide member body disposed in the first arc-shaped slide groove, and two limiting members fixedly connected to both sides of the first slide member body, and a portion of the second transition member is disposed between the two limiting members.

5. The hinge according to claim 3, wherein the first support base comprises a first support base body and a first support plate connected to a side of the first support base body, and one end of the first support plate close to the transition mechanism comprises the first slide member; and
wherein a side of the first support plate away from the first support base body is flush with a side of the first transition member away from the second transition member, when the at least two groups of second flip mechanisms are in an unfolded state;
wherein the second support base comprises a second support base body, a second support plate connected to one side of the second support base body, and an avoidance ramp fixedly connected to one end of the second support plate close to the transition mechanism;
the avoidance ramp is arranged separately from the transition mechanism; and
an angle between a surface of the avoidance ramp away from the second support base body and a surface of the second support plate away from the second support base body is an obtuse angle;
wherein the transition mechanism further comprises a third support seat body, and the second transition member is connected to a side of the third support seat body; and
wherein both a side of the third support seat body close to the first support base body and a side of the third support seat body close to the second support base body are arc-shaped.

6.-7. (canceled)

8. The hinge according to claim 1, wherein the first flip assembly comprises a first swing arm, a first adapter fixing member and a first flip plate;
one end of the first swing arm is rotatably connected to the first support base; the first adapter fixing member comprises a first straight slide groove, and the other end of the first swing arm is slidably connected to the first adapter fixing member within the first straight slide groove; and the first flip plate is rotatably connected to the first adapter fixing member; and
wherein a side of the first flip plate is configured to be abutted against a back of a flexible display panel in a foldable display device, and the first adapter fixing member is configured to be fixedly connected to a housing of the foldable display device, and the housing is fixedly connected to the back of the flexible display panel.

9. The hinge according to claim 8, wherein the first adapter fixing member comprises a first slide portion and a second slide portion on at least one side of the first slide portion;
the first slide portion comprises the first straight slide groove, and a second arc-shaped slide groove is defined in a side of the second slide portion away from the first slide portion; and
the first flip plate comprises a first flip plate body, and a second slide member fixedly connected to a side of the first flip plate body away from the flexible display panel, and at least a portion of the second slide member is within the second arc-shaped slide groove.

10. The hinge according to claim 9, wherein
the first slide portion further comprises a first hollow groove in communication with the first straight slide groove, and a portion of the first swing arm within the first straight slide groove comprises a second hollow groove in communication with the first hollow groove, and an inner wall of the second hollow groove comprises a third slide member; and
the first flip plate further comprises a raised portion fixedly connected to a side of the first flip plate body away from the flexible display panel, the raised portion successively passes through the first hollow groove and the second hollow groove, and a portion of the raised portion within the second hollow groove comprises a third arc-shaped slide groove; and
wherein at least a portion of the third slide member is within the third arc-shaped groove.

11. The hinge according to claim 8, wherein a side of the first straight slide groove comprises a limiting slide groove, an extension direction of the limiting slide groove is parallel to an extension direction of the first straight slide groove; and
a portion of the first swing arm disposed within the first straight slide groove comprises a limiting slide member, and at least a portion of the limiting slide member is disposed within the limiting slide groove.

12. The hinge according to claim 8, wherein one group of the first flip mechanisms further comprises two first synchronizing shafts, both of the two first synchronizing shafts are fixed in the first support base, and each of the two first synchronizing shafts is rotatably connected to one end of each of two the first swing arms in two first flip assemblies.

13. The hinge according to claim 12, wherein one group of the first flip mechanisms further comprises two second synchronizing shafts disposed between the two first synchronizing shafts, two first synchronous gears respectively sleeved on the two second synchronizing shafts, and the two first synchronous gears on the two second synchronizing shafts are engaged with each other; and one end of the first swing arm comprises a plurality of first outer teeth engaging with the first synchronous gear.

14. The hinge according to claim 12, wherein one group of the first flip mechanisms further comprises first torsion assemblies respectively connected to the two first synchronizing shafts, and the first torsion assemblies are configured to provide a damping force in response to rotation of two of the first flip assemblies relative to the first support base.

15. The hinge according to claim 9, wherein the first flip assembly further comprises a second swing arm and a second adapter fixing member; and
one end of the second swing arm is rotatably connected to the first support base and the other end of the second swing arm is rotatably connected to the second adapter fixing member; and the second adapter fixing member is rotatably connected to the first flip plate; and
wherein the second adapter fixing member is configured to be fixedly connected to the housing;
wherein at least one side of the second adapter fixing member comprises a fourth arc-shaped slide groove; and
the first flip plate further comprises a fourth slide member fixedly connected to a side of the first flip plate body away from the flexible display panel, and at least a portion of the fourth slide member is within the fourth arc-shaped slide groove;
wherein the first support base comprises a fifth arc-shaped slide groove, one end of the second swing arm comprises a fifth slide member cooperating with the fifth arc-shaped slide groove, and at least a portion of the fifth slide member is within the fifth arc-shaped slide groove;
wherein the first flip assembly further comprises a first connecting shaft fixed to a side of the second adapter fixing member away from the flexible display panel, and an end of the second swing arm away from the first support base is rotatably connected to the first connecting shaft; and
wherein the second adapter fixing member and the first adapter fixing member are of one-piece structure.

16.-19. (canceled)

20. The hinge according to claim 1, wherein the second flip assembly comprises a first drive rod and a second flip plate; and
one end of the first drive rod is rotatably connected to the second support base, and the other end of the first drive rod is fixedly connected to the second flip plate; and
wherein one side of the second flap is configured to abut against a back of a flexible display panel in a foldable display device; a first axis of an end of the first drive rod around which the end of the first drive rod is rotated relative to the second support base is on a side of the second support base close to the flexible display panel, and a specific distance is defined between the first axis and the second support base.

21. The hinge according to claim 20, wherein the second support base comprises a sixth arc-shaped slide groove, one end of the first actuating rod comprises a sixth slide member that cooperates with the sixth arc-shaped slide groove, and at least a portion of the sixth slide member is disposed within the sixth arc-shaped slide groove; and
wherein a length of the second straight slide groove is less than or equal to 3 mm.

22. The hinge according to claim 20, wherein the second flip assembly further comprises a second drive rod and a second connecting shaft; and
one end of the second drive rod is rotatably connected to the second support base and the other end of the second drive rod is fixedly connected to one end of the second connecting shaft, an end of the first drive rod away from the second support base comprises a second straight slide groove, and the other end of the second connecting shaft is slidingly connected to the first drive rod within the second straight slide groove; and
wherein a second axis of an end of the second drive rod around which the end of the second drive rod is rotated relative to the second support base is within the second support base, and the second axis is parallel to the first axis and an axis of the second connecting shaft.

23. The hinge according to claim 22, wherein one group of the second flip mechanisms further comprises two third synchronizing shafts, both of the third synchronizing shafts are fixed within the second support base, and each of the two third synchronizing shafts is rotatably connected to one end of each of two second drive rods in the two second flip assemblies;
wherein one group of the second flip mechanism furthers comprises two fourth synchronizing shafts disposed between the two third synchronizing shafts and two second synchronizing gears respectively sleeved on the two fourth synchronizing shafts, the two second synchronizing gears on the two fourth synchronizing shafts are engaged with each other, and a plurality of second external teeth engaging with one second synchronizing gear are arranged at one end of the second actuating rod; and
wherein one group of the second flip mechanisms further comprises two second torsion assemblies each of which is connected to each of the two third synchronizing shafts, and the two second torsion assemblies are configured to provide a damping force in response to rotation of the two second flip assemblies relative to the second support base.

24.-26. (canceled)

27. The hinge according to claim 1, wherein one first support base in each group of first flip mechanisms located on one side of the transition mechanism is of one-piece structure, one first support base in each group of first flip mechanisms on the other side of the transition mechanism is of one-piece structure, and a length of the first support base is greater in the first direction than a length of the first support base on the other side of the transition mechanism; and
one second support base in each of the groups of second flip mechanisms located on one side of the transition mechanism is of one-piece structure, one second support base in each of the groups of second flip mechanisms located on the other side of the transition mechanism is of one-piece structure and a length of the second support base on one side of the transition mechanism is equal to a length of the second support base on the other side of the transition mechanism in the second direction; and
wherein a maximum rotation angle of the first flip assembly relative to the first support base is greater than or equal to 90°, and a maximum rotation angle of the second flip assembly relative to the second support base is less than or equal to 45°.

28. (canceled)

29. A foldable display device, comprising: a flexible display panel, a housing, and the hinge as claimed in claim 1, wherein the housing is fixedly connected to a back of the flexible display panel and is fixedly connected to the hinge.

30. The foldable display device according to claim 29, wherein the housing comprises a first housing, a second housing, a third housing, and a fourth housing that are arranged separately; and
the first shell is connected to the second shell by at least one group of first flip mechanisms disposed on one side of the transition mechanism; the third shell is connected to the fourth shell by at least one group of first flip mechanisms on the other side of the transition mechanism; the first shell is connected to the third shell by at least one group of second flip mechanisms disposed on one side of the transition mechanism; and the second shell is connected to the fourth housing by at least one group of second flip mechanisms on the other side of the transition body.
